(19) United States
(12) Patent Application Publication
(10) Pub. No.: US 2026/0006915 A1
(43) Pub. Date: Jan. 1, 2026

(54) DISPLAY PANEL AND ELECTRONIC DEVICE INCLUDING THE SAME

(71) Applicant: Samsung Display Co., Ltd., Yongin-si (KR)

(72) Inventors: DOYEONG PARK, Yongin-si (KR); DONG HEE SHIN, Yongin-si (KR); YUNMI KIM, Yongin-si (KR); HYEONGSEOK KIM, Yongin-si (KR)

(21) Appl. No.: 19/060,184

(22) Filed: Feb. 21, 2025

(30) Foreign Application Priority Data
Jul. 1, 2024 (KR) 10-2024-0086084

(51) Int. Cl. H10D 86/40; G09G 3/32; G09G 3/3233

(52) U.S. Cl. CPC H10D 86/441; G09G 3/32; G09G 3/3233; G09G 2300/0819; G09G 2300/0842; G09G 2310/0286

(57) ABSTRACT

A display panel includes: a first stage including a first upper end region and a first lower end region adjacent to each other; a second stage spaced apart from the first stage, and including a second upper end region and a second lower end region adjacent to each other in a first direction; a plurality of pixels arranged in the first direction, and spaced apart from the first stage and the second stage in a second direction; a plurality of first output wires electrically connected to the first stage and the plurality of pixels; and a plurality of second output wires electrically connected to the second stage and the plurality of pixels, respectively, wherein the plurality of first output wires extend from the first lower end region of the first stage, and the plurality of second output wires extend from the second upper end region of the second stage.

### CROSS-REFERENCE TO RELATED APPLICATION

The present application claims priority to and the benefit of Korean Patent Application No. 10-2024-0086084, filed on Jul. 1, 2024, in the Korean Intellectual Property Office, the entire disclosure of which is incorporated herein by reference.

### BACKGROUND

Aspects of some embodiments of the present disclosure described herein relate to a display panel and an electronic device including the same.

Multimedia electronic devices, such as televisions, mobile phones, tablets, computers, navigation, or game consoles, include a display panel to display images. Recently, studies and research has been conducted to reduce a region, in which images are not displayed, from a display panel, to meet a user demand.

The above information disclosed in this Background section is only for enhancement of understanding of the background and therefore the information discussed in this Background section does not necessarily constitute prior art.

### SUMMARY

Aspects of some embodiments of the present disclosure described herein relate to a display panel and an electronic device including the same, and for example, to a display panel and an electronic device including the same a relatively reduced width of a non-display region.

Aspects of some embodiments of the present disclosure include a display panel and an electronic device including the same with a relatively reduced width of a non-display region.

According to some embodiments of the present disclosure, a display panel may include a first stage including a first upper end region and a first lower end region adjacent to each other in a first direction, a second stage spaced apart from the first stage in the first direction and including a second upper end region and a second lower end region adjacent to each other in the first direction, a plurality of pixels arranged in the first direction and spaced apart from the first stage and the second stage in a second direction crossing the first direction, a plurality of first output wires electrically connected to the first stage and the plurality of pixels, and a plurality of second output wires electrically connected to the second stage and the plurality of pixels, respectively, the plurality of first output wires may extend from the first lower end region of the first stage, and the plurality of second output wires may extend from the second upper end region of the second stage.

According to some embodiments of the present disclosure, each of the first stage and the second stage may be provided in a plurality, and the plurality of first stages and the plurality of second stages may be arranged while crossing each other in the first direction.

According to some embodiments of the present disclosure, the plurality of first output wires may include a (1-1)-th output wire, a (1-2)-th output wire, a (1-3)-th output wire, a (1-4)-th output wire, a (1-5)-th output wire, and a (1-6)-th output wire, and the plurality of second output wires may include a (2-1)-th output wire, a (2-2)-th output wire, a (2-3)-th output wire, a (2-4)-th output wire, a (2-5)-th output wire, and a (2-6)-th output wire.

According to some embodiments of the present disclosure, each of the plurality of first output wires and the plurality of second output wires may include a first part adjacent to the first stage and the second stage while extending in the second direction, a second part adjacent to the plurality of pixels while extending in the second direction, and a third part to connect the first part to the second part.

According to some embodiments of the present disclosure, the first part of each of the (1-1)-th output wire and the (1-2)-th output wire may be positioned under the second part, and the first part of each of the (1-4)-th output wire, the (1-5)-th output wire, and the (1-6)-th output wire may be positioned above the second part, when viewed in a plan view, the first part of the (2-1)-th output wire, the (2-2)-th output wire, the (2-3)-th output wire may be positioned under the second part, and the first part of the (2-5)-th output wire and the (2-6)-th output wire may be positioned above the second part, when viewed in a plan view.

According to some embodiments of the present disclosure, the first part, the second part, and the third part of each of the (1-3)-th output wire and the (2-4)-th output wire are arranged along the same line extending in the second direction, when viewed in a plan view.

According to some embodiments of the present disclosure, the first part of the (1-3)-th output wire may be positioned under the second part, and the first part of the (2-4)-th output wire is positioned above the second part, when viewed in a plan view.

According to some embodiments of the present disclosure, the third part may include an oblique part extending in a direction crossing the first direction and the second direction.

According to some embodiments of the present disclosure, the third part may include a plurality of connection parts, and at least a portion of the plurality of connection parts may extend in a mutually different direction.

According to some embodiments of the present disclosure, the display panel may further include a voltage wire interposed between the first stage and the second stage, and the plurality of pixels, and extending in the first direction.

According to some embodiments of the present disclosure, the voltage wire may include a first wire part, a second wire part, and a third wire part adjacent to each other in the first direction, and at least a portion of the second wire part of the voltage wire may be overlapped with the plurality of first output wires and the plurality of second output wires.

According to some embodiments of the present disclosure, a minimum width of each of the first wire part and the third wire part in the second direction may be greater than a minimum width of the second wire part in the second direction.

According to some embodiments of the present disclosure, the voltage wire may include a first wire pattern, a second wire pattern at a layer different from a layer for the first wire pattern, and a third wire pattern at a layer different from the layer for the first wire pattern and the layer for the second wire pattern, the first wire pattern, the second wire pattern, and the third wire pattern may be electrically connected to each other, and the plurality of first output wires may be at a layer the same as the layer for the third wire pattern, and the plurality of first output wires are spaced apart from the third wire pattern, when viewed in a plan view.

According to some embodiments of the present disclosure, each of the plurality of second output wires may include a first bridge part at a layer the same as the layer for the third wire pattern, and a second bridge part at a layer different from the layer for the third wire pattern, and the first bridge part may be overlapped with the voltage wire and spaced apart from the third wire pattern, when viewed in a plan view.

According to some embodiments of the present disclosure, an electronic device may include a first stage including a first upper end region and a first lower end region adjacent to the first upper end region in a first direction, a second stage spaced apart from the first stage in the first direction, and including a second upper end region and a second lower end region adjacent to the second upper end region in the first direction, a voltage wire spaced apart from the first stage and the second stage in a second direction crossing the first direction, while extending in the first direction, a plurality of first output wires extending in the second direction from the first stage, and crossing at least a portion of the voltage wire, when viewed in a plan view, and a plurality of second wires extending in the second direction from the second stage and crossing at least a portion of the voltage wire, when viewed in the plan view, the plurality of first output wires may from the first lower end region of the first stage, and the plurality of second output wires may extend from the second upper end region of the second stage.

According to some embodiments of the present disclosure, the plurality of first output wires may include a (1-1)-th output wire, a (1-2)-th output wire, a (1-3)-th output wire, a (1-4)-th output wire, a (1-5)-th output wire, and a (1-6)-th output wire, and the plurality of second output wires may include a (2-1)-th output wire, a (2-2)-th output wire, a (2-3)-th output wire, a (2-4)-th output wire, a (2-5)-th output wire, and a (2-6)-th output wire.

According to some embodiments of the present disclosure, the electronic device may include a plurality of pixels arranged in the first direction, and spaced apart from the first stage and the second stage in the second direction, each of the plurality of first output wires and the plurality of second output wires may include a first part adjacent to the first stage and the second stage while extending in the second direction, a second part adjacent to the plurality of pixels while extending in the second direction, and a third part to connect the first part to the second part. The first part of each of the (1-1)-th output wire and the (1-2)-th output wire is positioned under the second part, and the first part of each of the (1-4)-th output wire, the (1-5)-th output wire, and the (1-6)-th output wire is positioned above the second part, when viewed in the plan view, and the first part of the (2-1)-th output wire, the (2-2)-th output wire, the (2-3)-th output wire may be positioned under the second part, and the first part of the (2-5)-th output wire and the (2-6)-th output wire is positioned above the second part, when viewed in a plan view.

According to some embodiments of the present disclosure, the first part, the second part, and the third part of each of the (1-3)-th output wire and the (2-4)-th output wire may be arranged along the same line extending in the second direction, when viewed in the plan view.

According to some embodiments of the present disclosure, the first part of the (1-3)-th output wire may be positioned under the second part, and the first part of the (2-4)-th output wire is positioned above the second part, when viewed in the plan view.

According to some embodiments of the present disclosure, the voltage wire may include a first wire part, a second wire part, and a third wire part adjacent to each other in the first direction, and a minimum width of each of the first wire part and the third wire part in the second direction may be greater than a minimum width of the second wire part in the second direction.

### BRIEF DESCRIPTION OF THE DRAWINGS

The above and other objects and features of the present disclosure will become apparent by describing in detail embodiments thereof with reference to the accompanying drawings.

FIG. 1 is a perspective view of a electronic device according to some embodiments of the present disclosure.

FIG. 2 is a plan view illustrating a electronic device according to some embodiments of the present disclosure.

FIG. 3 is a block diagram of a electronic device according to some embodiments of the present disclosure.

FIG. 4 is an equivalent circuit diagram of a pixel according to some embodiments of the present disclosure.

FIG. 5 is a block diagram illustrating some components of the display panel according to some embodiments of the present disclosure.

FIG. 6A is a view illustrating a scan driving circuit according to some embodiments of the present disclosure.

FIG. 6B is an equivalent circuit diagram illustrating one stage according to some embodiments of the present disclosure.

FIG. 7 is a timing diagram to describe the operation of a stage in a first mode according to some embodiments of the present disclosure.

FIG. 8 is a timing diagram of a plurality of clock signals to describe the operation of a stage in a second mode according to some embodiments of the present disclosure.

FIG. 9 is a view illustrating an active stage and the change in brightness of a first scan signal and a second scan signal according to some embodiments of the present disclosure.

FIG. 10 is a view illustrating an active stage and the change in brightness of a first scan signal and a second scan signal according to some embodiments of the present disclosure.

FIG. 11 is a plan view illustrating a portion of the display panel according to some embodiments of the present disclosure.

FIG. 12 is an enlarged view illustrating region AA′ illustrated in FIG. 11 according to some embodiments of the present disclosure.

FIG. 13 is a cross-sectional view of a display panel DP taken along line I-I′ of FIG. 12 according to some embodiments of the present disclosure.

FIG. 14 is a cross-sectional view of a display panel DP taken along line II-II′ of FIG. 12 according to some embodiments of the present disclosure.

FIG. 15 is a plan view illustrating a portion of the display panel according to some embodiments of the present disclosure.

FIG. 16 is a plan view illustrating a portion of the display panel according to some embodiments of the present disclosure.

FIG. 17 is a plan view illustrating a portion of a display panel according to some embodiments of the present disclosure.

FIG. 18 is a plan view illustrating a portion of a display panel according to some embodiments of the present disclosure.

### DETAILED DESCRIPTION

In the specification, the expression that a first component (or region, layer, or part) is “on”, “connected to”, or “coupled to” a second component means that the first component is directly on, connected to, or coupled to the second component or means that a third component is interposed therebetween.

The same reference numeral will be assigned to the same component. In addition, in drawings, thicknesses, proportions, and dimensions of components may be exaggerated to describe the technical features effectively. The term “and/or” includes any and all combinations of one or more of associated components

Although the terms “first”, or “second” may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and will be described with reference to a direction indicated in the drawing.

It will be further understood that the terms “comprises,” “comprising,” “includes,” or “including,” or “having” specify the presence of stated features, numbers, steps, operations, components, parts, or the combination thereof, but do not preclude the presence or addition of one or more other features, numbers, steps, operations, components, components, and/or the combination thereof.

The terms “part” and “unit” refer to a software component or a hardware component to perform a specific function. The hardware component may include field-programmable gate array (FPGA) or an application-specific integrated circuit (ASIC).

Software components may indicate data used by executable codes and/or executable codes in a storage medium which is able to be addressed. Accordingly, software components may be, for example, object-oriented software components, class components, and task components, and may include processes, functions, properties, procedures, subroutines, program code segments, driver data, firmware, micro codes, circuits, data, database, data structures, tables, arrangements or variables.

Unless defined otherwise, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, aspects of some embodiments of the present disclosure will be described in more detail with reference to the drawings.

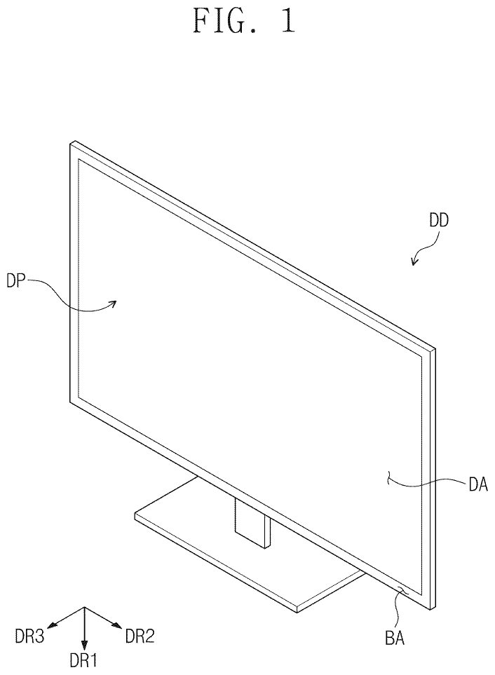

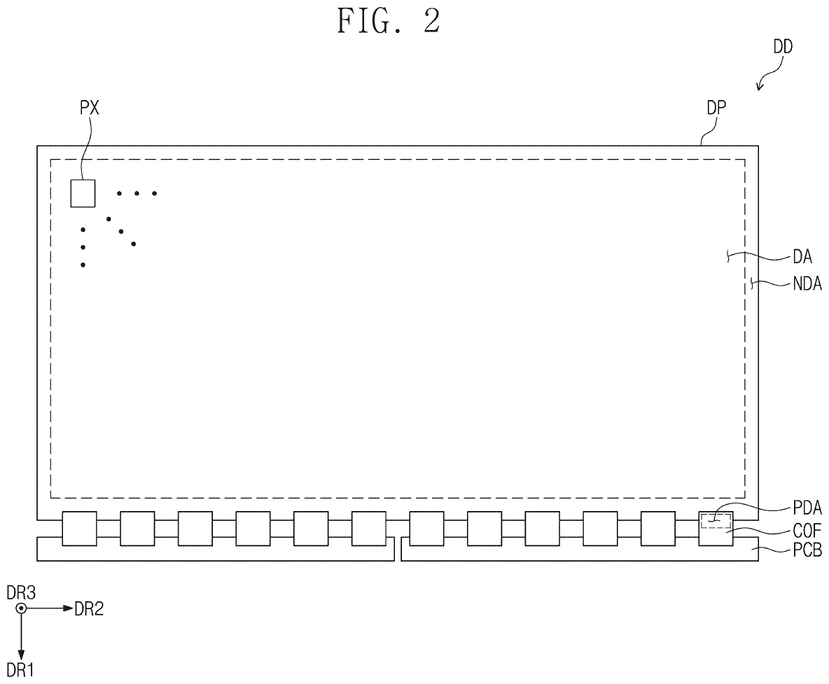

FIG. 1 is a perspective view of a electronic device DD according to some embodiments of the present disclosure. FIG. 2 is a plan view of the electronic device DD according to some embodiments of the present disclosure.

Referring to FIGS. 1 and 2, the electronic device DD is a device activated in response to an electrical signal. Embodiments according to the present disclosure may be incorporated into an electronic device, such as small and medium-size electronic devices, such as a personal computer, a notebook computer, a personal digital terminal, a vehicle navigation unit, a game console, a portable electronic device, and a camera, in addition to large-size electronic equipment, such as a television, a monitor, or an outside billboard. In addition, the above examples are provided only as an example, and according to some embodiments the electronic device DD may be applied to any other electronic device(s) without departing from the concept of the present disclosure. The electronic device DD illustrated in FIG. 1 may be a monitor.

The electronic device DD may include a display panel DP, a connection film COF, and a circuit board PCB.

The display panel DP may be a component to actually generate an image. The display panel DP may be an emissive-type display panel. For example, the display panel DP may be an organic light emitting display panel, an inorganic light emitting display panel, an organic-inorganic light emitting display panel, a quantum dot display panel, a micro-LED display panel, or a nano-LED display panel, but embodiments according to the present disclosure are not limited thereto. The display panel DP may have a small and medium-sized size of several inches or tens of inches or less. Alternatively, the display panel DP may have a larger size of at least several tens of inches.

The display panel DP may include a display region DA and a non-display region NDA. The display panel DP may display an image through the display region DA. For example, the display panel DP may include a plurality of pixels PX and the pixels PX may be located in the display region DA. The display region DA may include a plane defined by a first direction DR1 and a second direction DR2. The display region DA may display images in a third direction DR3 crossing the first direction DR1 and the second direction DR2. The non-display region NDA may surround a peripheral portion of the display region DA.

A plurality of connection films COF may be provided. Each of the plurality of connection films COF may include a driving circuit, such as a data driving circuit, mounted thereon, to drive the display panel DP. The connection films COF may be coupled to the non-display region NDA of the display panel DP. For example, the connection films COF may be attached to one side of the display panel DP. According to some embodiments of the present disclosure, the connection films COF may be coupled to the pad region PDA of the display panel DP. The pad region PDA may be defined in the non-display region NDA of the display panel DP. The connection films COF may be coupled to the display panel DP through an anisotropic conductive film (ACF), but embodiments according to the present disclosure are not limited thereto.

A plurality of circuit boards PCB may be provided. Each of the plurality of circuit boards PCB may be electrically connected to the display panel DP through relevant some films of the connection films COF. Each of the circuit boards PCB may include a chip, such as a timing controller, mounted thereon to control the operation of the display panel DP.

Although FIG. 2 illustrates sixth connection films COF, embodiments according to the present disclosure are not limited thereto. Although FIG. 2 illustrates two circuit boards PCB, embodiments according to the present disclosure are not limited thereto. For example, the number of the connection films COF and the number of circuit boards PCB may be varied depending on the resolution of the display panel DP, the size of the display panel DP, and the specification of a data driving circuit.

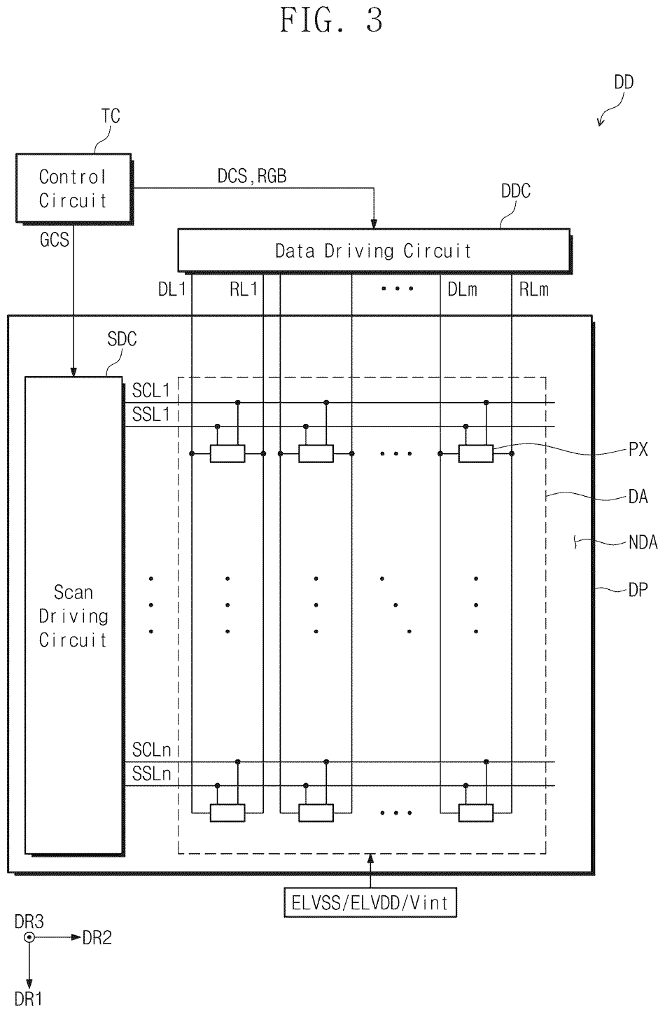

FIG. 3 is a block diagram of the electronic device DD according to some embodiments of the present disclosure.

Referring to FIGS. 2 and 3, the electronic device DD may include the display panel DP, a scan driving circuit SDC, a data driving circuit DDC, and a control circuit TC.

The display panel DP includes the display region DA for displaying images and the non-display region NDA located outside (e.g., in a periphery or outside a footprint of) the display region DA. The display region DA may include a plurality of pixels PX located therein. The non-display region NDA may include the scan driving circuit SDC located therein to drive the pixels PX.

The scan driving circuit SDC may be directly formed on a base layer through a photolithography process. For example, the scan driving circuit SDC may be formed simultaneously with the pixel circuit through the process for forming the pixel circuit of the pixels PX.

The control circuit TC controls the driving of the scan driving circuit SDC and the data driving circuit DDC. The control circuit TC transform a data format of image signals to match an interface specification with the data driving circuit DDC to generate image data RGB. The control circuit TC outputs the image data RGB and various control signals DCS and GCS.

The scan driving circuit SDC receives the first control signal GCS from the control circuit TC. The first control signal GCS may include a vertical starting signal to start the operation of the scan driving circuit SDC, and a clock signal for determining output timing of signals. The scan driving circuit SDC may output a plurality of scan signals to a plurality of output wires SCL1 to SCLn, and SSL1 to SSLn. The number of the output wires SCL1 to SCLn, and SSL1 to SSLn may be ‘n’, and ‘n’ may be an integer number equal to or greater than ‘2’. The scan driving circuit SDC may be referred to as a gate driving circuit.

The data driving circuit DDC receives the second control signal DCS and the image data RGB from the control circuit TC. The data driving circuit DDC transforms the image data RGB into data signals, and outputs the data signals to the plurality of data wires DL1 to DLm. The number of the plurality of data wires DL1 to DLm may be ‘m’, and ‘m’ may be an integer number equal to or greater than ‘2’. The data signals may be analog voltages corresponding to gray values of the image data RGB. The data driving circuit DDC may be provided in the form of a driving chip to be mounted on the connection films COF, on the circuit boards PCB, or in the non-display region NDA of the display panel DP illustrated in FIG. 2,

The display panel DP may include the plurality of output wires SCL1 to SCLn, and SSL1 to SSLn, the plurality of data wires DL1 to DLm, a plurality of read-out wires RL1 to RLm, and the plurality of pixels PX.

The output wires SCL1 to SCLn, and SSL1 to SSLn may be arranged in the first direction DR1, and each of the output wires SCL1 to SCLn, and SSL1 to SSLn may extend in the second direction DR2 crossing the first direction DR1. The output wires SCL1 to SCLn, and SSL1 to SSLn may include the first output wires SCL1 to SCLn and the second output wires SSL1 to SSLn. The first output wires SCL1 to SCLn may be referred to write scan wires or the first gate wires, and the second output wires SSL1 to SSLn may be referred to initializing scan wires, sensing scan wires, or second gate wires.

The data wires DL1 to DLm may be arranged in the second direction DR2, and each of the data wires DL1 to DLm may extend in the first direction DR1. The read-out wires RL1 to RLm may be arranged in the second direction DR2, and each of the read-out wires RL1 to RLm may extend in the first direction DR1. The data wires DL1 to DLm and the read-out wires RL1 to RLm may be insulated from the output wires SCL1 to SCLn, and SSL1 to SSLn while crossing the output wires SCL1 to SCLn, and SSL1 to SSLn.

Each of the pixels PX may be connected to relevant output wires of the output wires SCL1 to SCLn, and SSL1 to SSLn, a relevant data wire of the data wires DL1 to DLm, and a relevant read-out wire of the read-out wires RL1 to RLm. For example, the pixels PX arranged in a first row may be electrically connected to the first-positioned first output wire SCL1 and the first-positioned second output wire SSL1, and the pixels PX arranged in an n-th row may be electrically connected to the n-th-positioned first output wire SCLn and the n-th-positioned second output wire SSLn.

The pixels PX arranged in a first column may be electrically connected to the first data wire DL1 and the first read-out wire RL1, and the pixels PX arranged in an m-th column may be electrically connected to the m-th data wire DLm and the m-th read out wire RLm. However, this is provided only for the illustrative purpose, and the relationship among the pixels PX, the output wires SCL1 to SCLn, and SSL1 to SSLn, the data wires DL1 to DLm, and the read-out wires RL1 to RLm is not limited thereto.

The display panel DP may receive a first power supply voltage ELVDD and a second power supply voltage ELVSS. The first power supply voltage ELVDD may be 1 supplied to the pixels PX. The display panel DP may receive an initializing voltage Vint. The initializing voltage Vint may be supplied to the pixels PX.

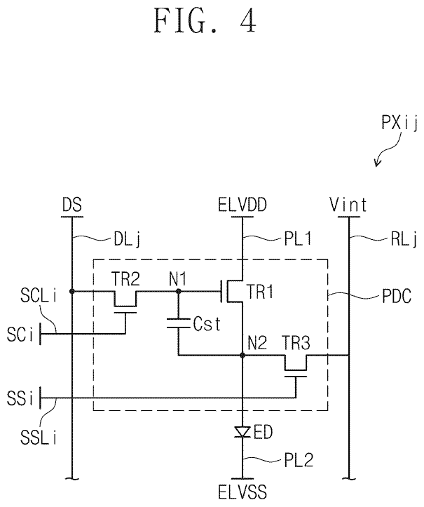

FIG. 4 is an equivalent circuit diagram of a pixel PXij according to some embodiments of the present disclosure. Although FIG. 4 illustrates various components in a pixel according to some embodiments of the present disclosure, embodiments according to the present disclosure are not limited thereto, and according to various embodiments, the pixel may include additional components or fewer components without departing from the spirit and scope of embodiments according to the present disclosure.

FIG. 4 illustrates an equivalent circuit diagram of the pixel PXij of the plurality of pixels PX (see FIG. 3). Because the plurality of pixels PX has the same equivalent circuit structure, the circuit structure of the pixel PXij will be representatively described, and the details of remaining pixels PX will be omitted. In this case, ‘i’ may be an integer ranging from ‘1’ to ‘n’, and ‘j’ may be an integer ranging from ‘1’ to ‘m’.

Referring to FIG. 4, the pixel PXij may include a light emitting element ED and a pixel driving circuit PDC. The pixel PXij may be electrically connected to i-th output wires SCLi and SSLi of the output wires SCL1 to SCLn, and SSL1 to SSLn, a j-th data wire DLj of the data wires DL1 to DLm, and a j-th read-out wire RLj of the read-out wires RL1 to RLm. The i-th output wires SCLi and SSLi in the i-th row may include the i-th first output wire SCLi and the i-th second output wire SSLi.

The pixel driving circuit PDC may include a first transistor TR1, a second transistor TR2, a third transistor TR3, and a capacitor Cst. A configuration of the pixel driving circuit PDC according to the present disclosure is not limited to the embodiments illustrated in FIG. 4. The pixel driving circuit PDC illustrated in FIG. 2 is provided for the illustrative purpose, and the configuration of the pixel driving circuit PDC may be modified and implemented. For example, the pixel driving circuit PDC may further include at least one transistor and at least one capacitor.

According to some embodiments of the present disclosure, in the following description, each of the first transistor TR1, the second transistor TR2, and the third transistor TR3 may be a N-type thin film transistor. However, embodiments according to the present disclosure are not limited thereto. For example, at least any one of the first transistor TR1, the second transistor TR2, and the third transistor TR3 may be a P-type thin film transistor.

In addition, each of the first transistor TR1, the second transistor TR2, and the third transistor TR3 may be a transistor having an oxide semiconductor layer. However, embodiments according to the present disclosure are not limited thereto. For example, at least one of the first transistor TR1, the second transistor TR2, or the third transistor TR3 may be a transistor having a low-temperature polycrystalline silicon (LTPS) semiconductor layer.

The first transistor TR1 may be electrically connected between a first power wire PL1 and the light emitting element ED. The first transistor TR1 may include a gate electrode connected to a first node N1, a first electrode electrically connected to the first power wire PL1 and a second electrode connected to the light emitting element ED. The light emitting element ED and the first transistor TR1 may be electrically connected to each other at a second node N2. The first power supply voltage ELVDD may be applied to the pixel PXij through the first power wire PL1

The first transistor TR1 may control an amount of current flowing through the light emitting element ED, depending on the voltage at the first node N1. For example, the first transistor TR1 may be turned on, when the voltage (that is, a gate-source voltage) between the first node N1 and the second node N2 is higher than a threshold voltage.

The second transistor TR2 may be electrically connected between the j-th data wire DLj and the first node N1. The second transistor TR2 may include a gate electrode connected to the i-th first output wire SCLi, a first electrode connected to the j-th data wire DLj, and a second electrode connected to the first node N1.

The second transistor TR2 may transmit a data voltage DS, which is received from the j-th data wire DLj, to the first node N1, in response to an i-th first scan signal SCi which is applied through the i-th first output wire SCLi. For example, the second transistor TR2 may be turned on, when the i-th first scan signal SCi is in a logic-high level.

The third transistor TR3 may be electrically connected between the second node N2 and the j-th read-out wire RLj. The third transistor TR3 may include a gate electrode connected to the i-th second output wire SSLi, a first electrode connected to the j-th read-out wire RLj, and a second electrode connected to the second node N2. The third transistor TR3 may be connected between the second node N2 and the j-th read-out wire RLj, in response to the i-th second scan signal SSi applied through the i-th second output wire SSLi. For example, the third transistor TR3 may be turned on when the i-th second scan signal SSi is in a logic-high level.

According to some embodiments of the present disclosure, in an image display operation, the third transistor TR3 may transmit the initializing voltage Vint to the second node N2, in response to the i-th second scan signal SSi. In other words, when the third transistor TR3 is turned on, the second electrode of the first transistor TR1 may be reset to the initializing voltage Vint.

In a sensing operation, the third transistor TR3 may transmit a sensing current, which corresponds to a voltage at the second node N2, to the j-th read-out wire RLj, in response to the i-th second scan signal SSi. The control circuit TC (see FIG. 3) may receive the sensing current to determine the threshold voltage of the first transistor TR1 or the mobility, such that compensated image data RGB is generated. The capacitor Cst may be connected between the first node N1 and the second node N2. When the data voltage DS is supplied, the initializing voltage Vint may be supplied to the second node N2. In this case, the differential voltage between the data voltage DS and the initializing voltage Vint may be stored in the capacitor Cst. Whether the first transistor TR1 is turned on or turned off may be determined depending on the voltage stored in the capacitor Cst.

The light emitting element ED may be connected between the second node N2 and a second power wire PL2. The second power supply voltage ELVSS may be applied to the second power wire PL2. The light emitting element ED may include a first electrode (for example, an anode), a second electrode (for example, a cathode), and a light emitting layer between the first electrode and the second electrode. For example, the first electrode may be connected to the second node N2, and the second electrode may be connected to the second power wire PL2. The light emitting element

ED may generate light having a specific brightness to correspond to an amount of current applied from the first transistor TR1.

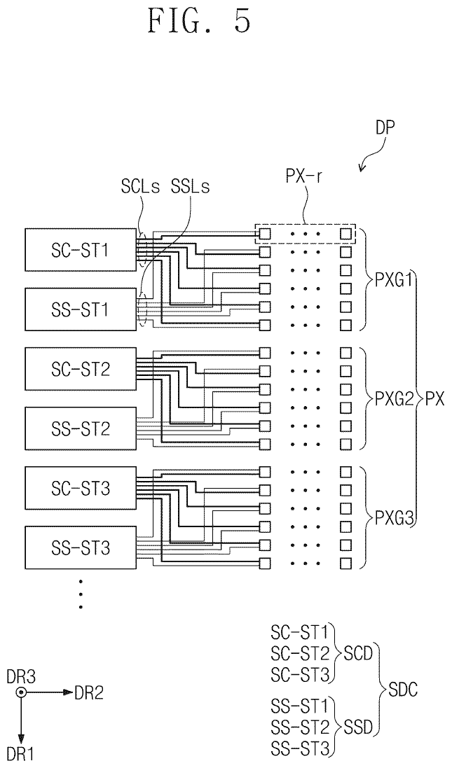

FIG. 5 is a block diagram illustrating some components of the display panel DP according to some embodiments of the present disclosure.

Referring to FIG. 5, a portion of the scan driving circuit SDC and pixels PX are illustrated. The scan driving circuit SDC may include a first scan driving circuit SCD and a second scan driving circuit SSD. The first scan driving circuit SCD may include a plurality of first stages SC-ST1, SC-ST2, and SC-ST3, and the second scan driving circuit SSD may include a plurality of second stages SS-ST1, SS-ST2, and SS-ST3.

According to some embodiments of the present disclosure, the first stages SC-ST1, SC-ST2, and SC-ST3 may be arranged in the first direction DR1, and the second stages SS-ST1, SS-ST2, and SS-ST3 may be spaced apart from the first stages SC-ST1, SC-ST2, and SC-ST3, respectively in the first direction DR1, and may be arranged in the first direction DR1. In addition, the first stages SC-ST1, SC-ST2, and SC-ST3 and the second stages SS-ST1, SS-ST2, and SS-ST3 may be alternately and repeatedly arranged one by one in the first direction DR1.

According to some embodiments of the present disclosure, the first stages SC-ST1, SC-ST2, and SC-ST3 may be electrically connected to the plurality of first output wires SCLs, respectively. In addition, the second stages SS-ST1, SS-ST2, and SS-ST3 may be electrically connected to the plurality of second output wires SSLs, respectively. For example, one first stage SC-ST1 may be connected to ‘Y’ number of first scan wires SCLs to output ‘Y’ number of first scan signals, and one second stage SS-ST1 may be connected to ‘Y’ number of second scan wires SSLs to output ‘Y’ number of second scan signals. In this case, ‘Y’ may be an integer equal to or greater than ‘2’.

Although FIG. 5 illustrates that one first stage SC-ST1 may be electrically connected to six first scan wires SCLs, and one second stage SS-ST1 may be electrically connected to sixth second scan wires SSLs, embodiments according to the present disclosure are not limited thereto. For example, one first stage SC-ST1 may be electrically connected to at least two first scan wires SCLs, and one second stage SS-ST1 may be electrically connected to at least two second scan wires SSLs.

In FIG. 5, although a first-positioned first stage SC-ST1 is located above a first-positioned second stage SS-ST1 when viewed in a plan view, embodiments according to the present disclosure are not limited thereto. For example, the first-positioned second stage SS-ST1 may be located above the first-positioned first stage SC-ST1, and the first-positioned second stage SS-ST1 and the first-positioned first stage SC-ST1 may be arranged while crossing each other in the first direction.

According to some embodiments of the present disclosure, the plurality of pixels PX may be arranged in the first direction DR1 and the second direction DR2. One row of pixels PX-r (hereinafter, referred to as a “pixel row”), which are arranged in the second direction DR2, of the plurality of pixels PX may be electrically connected to one first stage SC-ST1 and one second stage SS-ST1. In addition, the pixels PX may include ‘Y’ rows of pixels PXG1 (hereinafter, referred to as a “first pixel groups”) arranged in the first direction DR1, and the first pixel groups PXG1 may be electrically connected to the one first stage SC-ST1 and the one second stage SS-ST1. The first pixel groups PXG1 may be electrically connected to the first output wires SCLs extending from the one first stage SC-ST1 and the second output wires SSLs extending from the one second stage SS-ST1.

The first pixel groups PXG1 including six pixel rows PX-r may be electrically connected to the first-positioned first stage SC-ST1 and the first-positioned second stage SS-ST1. A second pixel group PXG2 including six pixel rows PX-r next to the first pixel groups PXG1 may be electrically connected to a second-positioned first stage SC-ST2 and a second-positioned second stage SS-ST2. A third pixel group PXG3 including six pixel rows PX-r next to the second pixel groups PXG2 may be electrically connected to a third-positioned first stage SC-ST3 and a third-positioned second stage SS-ST3.

According to some embodiments of the present disclosure, one stage, such as the first stage SC-ST1, may control the operation of a pixel group, such as the first pixel group PXG1, including at least two pixel rows PX-r. In other words, the number of total stages may be smaller than the number of rows of the pixels PX. Accordingly, the number of transistors, capacitors, and wires (for example, clock wires) located in the non-display region NDA (see FIG. 3) may be reduced. Accordingly, the width of the non-display region NDA (see FIG. 3) of the display panel DP (see FIG. 2) may be reduced.

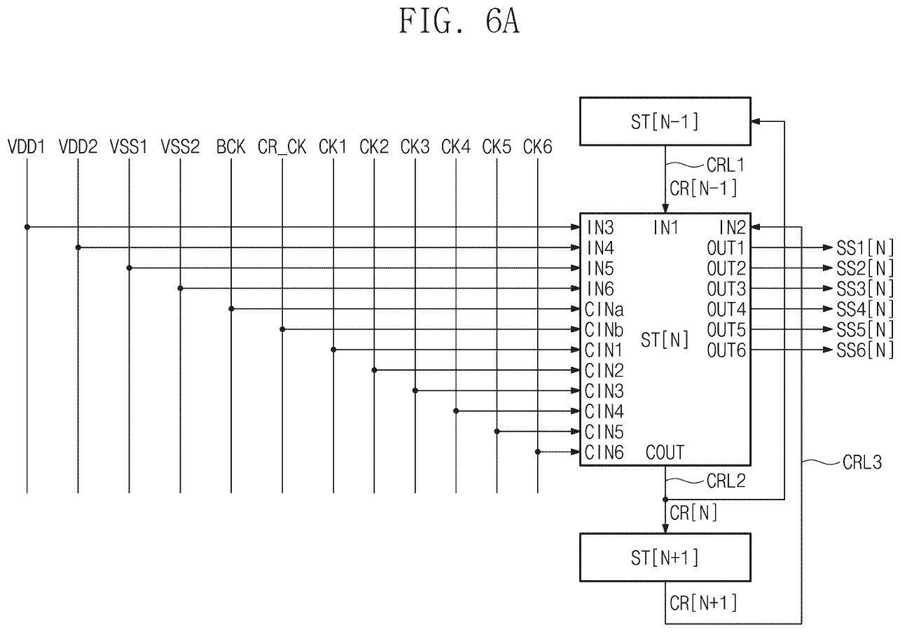

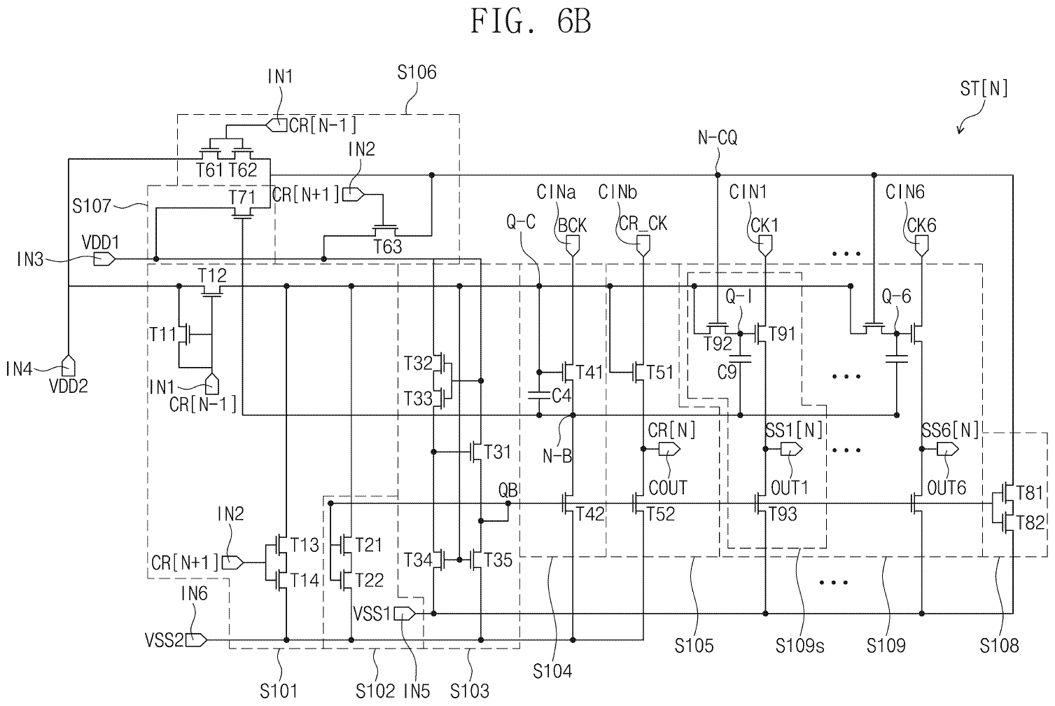

FIG. 6A is a view illustrating the scan driving circuit SDC according to some embodiments of the present disclosure. FIG. 6B is an equivalent circuit diagram illustrating one stage ST[N] according to some embodiments of the present disclosure. Although FIG. 6B illustrates various components in a stage according to some embodiments of the present disclosure, embodiments according to the present disclosure are not limited thereto, and according to various embodiments, the stage may include additional components or fewer components without departing from the spirit and scope of embodiments according to the present disclosure.

FIG. 6A illustrates three stages ST[N−1], ST[N], and ST[N+1]. In this case, ‘N’ may be an integer equal to or greater than ‘2’. The three stages ST[N−1], ST[N], and ST[N+1] may be first stages SC-ST1, SC-ST2, and SC-ST3 (see FIG. 5), or second stages SS-ST1, SS-ST2, and SS-ST3 (see FIG. 5).

FIG. 6B illustrates an equivalent circuit diagram of one stage ST[N]. Because remaining stages ST[N−1] and ST[N+1] substantially include the same configuration as the stage ST[N], the duplication thereof will be omitted. The configuration of one stage ST[N] according to some embodiments of the present disclosure is not limited to the embodiments illustrated in FIG. 6B. One stage ST[N] illustrated in FIG. 6B is provided only for the illustrative purpose, and the circuit configuration of the stage ST[N] may be modified.

Referring to FIG. 6A, the stages ST[N−1], ST[N], and ST[N+1] may be sequentially referred to as the first peripheral stage ST[N−1], the reference stage ST[N], and the second peripheral stage ST[N+1]. Alternatively, the reference stage ST[N] may be simply referred to as the stage ST[N]. Hereinafter, the reference stage ST[N] will be referred to as the stage ST[N].

The stage ST[N] may include first to sixth input terminals IN1, IN2, IN3, IN4, IN5, and IN6, first to sixth clock terminals CIN1, CIN2, CIN3, CIN4, CIN5, and CIN6, a first control terminal CINa, a second control terminal CINb, first to sixth output terminals OUT1, OUT2, OUT3, OUT4, OUT5, and OUT6, and a carry output terminal COUT.

The first input terminal IN1 of the stage ST[N] may receive a carry signal CR[N−1] output from a previous stage, such as the first peripheral stage ST[N−1]. When the stage ST[N] is the first stage, the first input terminal IN1 may receive a start signal output from a previous dummy stage before the first stage.

The carry signal CR[N−1] may be referred to as a previous carry signal, or a first carry signal. Hereinafter, the carry signal CR[N−1] may be referred to as the first carry signal CR[N−1]. The first peripheral stage ST[N−1] and the stage ST[N] may be electrically connected to a first carry wire CRL1, and the first carry wire CRL1 may be referred to as a first peripheral wire. The first carry signal CR[N−1]) generated from the first peripheral stage ST[N−1] may be transmitted to the stage ST[N] through the first carry wire CRL1.

The second input terminal IN2 of the stage ST[N] may receive the carry signal CR[N+1] output from a next stage, such as the second peripheral stage ST[N+1]. When the stage ST[N] is the last stage, the second input terminal IN2 may receive a carry signal output from a dummy stage next to the last stage.

The carry signal CR[N+1] may be referred to as a next carry signal, or a third carry signal. Hereinafter, the carry signal CR[N+1] may be referred to as the third carry signal CR[N+1]. The second peripheral stage ST[N+1] and the stage ST[N] may be electrically connected to the third carry wire CRL3, and the third carry wire CRL3 may be referred to as the second peripheral wire. The third carry signal CR[N+1]) generated from the second peripheral stage ST[N+1] may be transmitted to the stage ST[N] through the third carry wire CRL3.

The third input terminal IN3 of the stage ST[N] may receive a first high voltage VDD1 and the fourth input terminal IN4 of the stage ST[N] may receive a second high voltage VDD2. The voltage level of the second high voltage VDD2 may be greater than the voltage level of the first high voltage VDD1, but embodiments according to the present disclosure are not limited thereto. For example, the first high voltage VDD1 may be 15 V, and the second high voltage VDD2 may be 25 V.

The fifth input terminal IN5 of the stage ST[N] may receive a first low voltage VSS1, and the sixth input terminal IN6 of the stage ST[N] may receive a second low voltage VSS2. The voltage level of the first low voltage VSS1 and the voltage level of the second low voltage VSS2 may be equal to each other or may be different from each other.

The stage ST[N] may receive a boost clock signal BCK through the first control terminal CINa, and may receive a carry clock signal CR_CK through the second control terminal CINb. The stage ST[N] may receive the first to sixth clock signals CK1, CK2, CK3, CK4, CK5, and CK6 through the first to sixth clock terminals CIN1, CIN2, CIN3, CIN4, CIN5, and CIN6. According to some embodiments of the present disclosure, the first to sixth clock terminals CIN1, CIN2, CIN3, CIN4, CIN5, and CIN6 of each of the first peripheral stage ST[N−1] and the second peripheral stage ST[N+1] may receive clock signals having phases inverse to phases of the first to sixth clock signals CK1, CK2, CK3, CK4, CK5, and CK6.

The carry output terminal COUT of the stage ST[N] may output the carry signal CR[N]. The carry signal CR[N] may be transmitted to the first peripheral stage ST[N−1] and the second peripheral stage ST[N+1]. The carry signal CR[N] may be referred to as a second carry signal. Hereinafter, the carry signal CR[N] will be referred to as the second carry signal CR[N]. The first peripheral stage ST[N−1], the stage ST[N], and the second peripheral stage ST[N+1] may be electrically connected to the second carry wire CRL2. The second carry signal CR[N generated from the stage ST[N] may be transmitted to the first peripheral stage ST[N−1] and the second peripheral stage ST[N+1] through the second carry wire CRL2.

The first to sixth output terminals OUT1, OUT2, OUT3, OUT4, OUT5, and OUT6 of the stage ST[N] may output the first to sixth scan signals SS1[N], SS2[N], SS3[N], SS4[N], SS5[N], and SS6[N], respectively. The first to sixth scan signals SS1[N], SS2[N], SS3[N], SS4[N], SS5[N], and SS6[N] may be applied to, for example, pixels in six rows belonging to the second pixel group PXG2.

The first to sixth scan signals SS1[N], SS2[N], SS3[N], SS4[N], SS5[N], and SS6[N] may be the first scan signals (or referred to as “first-type scan signals) applied through the first output wires SCLs (see FIG. 5). Alternatively, the first to sixth scan signals SS1[N], SS2[N], SS3[N], SS4[N], SS5[N], and SS6[N] may be the second scan signals (or referred to as “second-type scan signals) applied through the second output wires SSLs (see FIG. 5).

Referring to FIG. 6B, one stage ST[N] may include a first node Q-C, a second node QB, a third node N-CQ, a fourth node N-B, and a plurality of divided nodes Q-1 to Q-6. The first node Q-C may be referred to as a Q node, the divided 1 nodes Q-1 to Q-6 may be referred to as divided Q nodes, and the second node QB may be referred to as a QB node.

In addition one stage ST[N] may further include a first circuit S101, a second circuit S102, a third circuit S103, a fourth circuit S104, a fifth circuit S105, a sixth circuit S106, a seventh circuit S107, an eighth circuit S108, and a ninth circuit S109.

The first circuit S101 may control the voltage at the first node Q-C, and may be referred to as a first node control circuit. The first circuit S101 may include the first to fourth transistor T11, T12, T13, and T14.

The first transistor T11 and the second transistor T12 may be connected to each other in series, and the first transistor T11 and the second transistor T12 may have a dual gate structure. The first transistor T11 and the second transistor T12 may be connected to each other between the first input terminal IN1 and the first node Q-C. Alternatively, a gate electrode of the first transistor T11 and a gate electrode of the second transistor T12 are all connected to the first input terminal IN1. A fourth input terminal IN4 may be connected between the first transistor T11 and the second transistor T12. The first transistor T11 and the second transistor T12 may be turned on in response to a gate on-voltage (for example, a logic-high level) of the first carry signal CR[N−1], and the second transistor T12 may transmit the second high voltage VDD2 to the first node Q-C. The operation of transmitting the second high voltage VDD2 to the first node Q-C may be referred to as a pre-charging operation or a primary boosting operation.

The third transistor T13 and the fourth transistor T14 may be connected to each other in series, and the third transistor T13 and the fourth transistor T14 may have a dual gate structure. The third transistor T13 and the fourth transistor T14 may be connected between the first node Q-C and the sixth input terminal IN6. Alternatively, a gate electrode of the third transistor T13 and a gate electrode of the fourth transistor T14 are all connected to the second input terminal IN2. The third transistor T13 and the fourth transistor T14 may transmit the second low voltage VSS2 to the first node Q-C, in response to the gate-on voltages (for example, a logic-high level) of the third carry signal CR[N+1].

The second circuit S102 may include a first transistor T21 and a second transistor T22. The first transistor T21 and the second transistor T22 may be connected to each other in series, and the first transistor T21 and the second transistor T22 may be connected between the first node Q-C and the sixth input terminal IN6. Alternatively, a gate electrode of the first transistor T21 and a gate electrode of the second transistor T22 are all connected to the second node QB. The first transistor T21 and the second transistor T22 may transmit the second low voltage VSS2 to the first node Q-C in response to the voltage at the second node QB. Accordingly, the second circuit S102 may be referred to as a first node stabilization circuit.

The third circuit S103 may include a first transistor T31, a second transistor T32, a third transistor T33, a fourth transistor T34, and a fifth transistor T35.

The first transistor T31 may be connected between the second node QB and

the third input terminal IN3. The second transistor T32 and the third transistor T33 may be connected to each other in series, and a gate electrode of the second transistor T32 and a gate electrode of the third transistor T33 may be connected to the third input terminal IN3. The second transistor T32 and the third transistor T33 may be connected between the third input terminal IN3 and a gate electrode of the first transistor T31.

The fourth transistor T34 may be connected between the gate electrode of the first transistor T31 and the fifth input terminal IN5, and the fifth transistor T35 may be connected between the second node QB and the sixth input terminal IN6. A gate electrode of the fourth transistor T34 and a gate electrode of the fifth transistor T35 are all connected to the first node Q-C.

The second transistor T32 and the third transistor T33 transmit the first high voltage VDD1 to the gate electrode of the first transistor T31, in response to the first high voltage VDD1. The operation of the fourth transistor T34 may be controlled in response to the voltage at the first node Q-C. When the fourth transistor T34 is turned 1 on, the first low voltage VSS1 may be transmitted to the gate electrode of the first transistor T31.

The first transistor T31 may transmit the first high voltage VDD1 to the second node QB, in response to the voltage of the gate electrode of the first transistor T31. The operation of the fifth transistor T35 may be controlled in response to the voltage at the first node Q-C. When the fifth transistor T35 is turned on, the second low voltage VSS2 may be transmitted to the second node QB.

The fourth circuit S104 may include a first transistor T41, a second transistor T42, and a capacitor C4.

The first transistor T41 may be connected between the first control terminal CINa and the fourth node N-B. A gate electrode of the first transistor T41 may be connected to the first node Q-C. The operation of the first transistor T41 may be controlled in response to the voltage at the first node Q-C. When the first transistor T41 is turned on, the fourth node N-B may receive a voltage in a logic-high level.

The second transistor T42 may be connected between the fourth node N-B and the sixth input terminal IN6. A gate electrode of the second transistor T42 may be connected to the second node QB. The operation of the second transistor T42 may be controlled in response to the voltage at the second node QB. When the second transistor T42 is turned on, the second low voltage VSS2 may be supplied to the fourth node N-B.

The capacitor C4 is connected to a gate terminal of the first transistor T41 and the fourth node N-B. The capacitor C4 may increase (boost up) the voltage at the first node Q-C to correspond to the increase in voltage at the fourth node N-B.

The fifth circuit S105 may include a first transistor T51 and a second transistor T52.

The first transistor T51 may be connected between the second control terminal CINb and the carry output terminal COUT. A gate electrode of the first transistor T51 may be connected to the first node Q-C. The operation of the first transistor T51 may be controlled in response to the voltage at the first node Q-C. When the first transistor T51 is turned on, a logic-high level voltage of the second carry signal CR[N] may be supplied to the carry output terminal COUT.

The second transistor T52 may be connected between the carry output terminal COUT and the sixth input terminal IN6. A gate electrode of the second transistor T52 may be connected to the second node QB. The operation of the second transistor T52 may be controlled in response to the voltage at the second node QB. When the second transistor T52 is turned on, the second low voltage VSS2 may be transmitted to the carry output terminal COUT.

The sixth circuit S106 may control the voltage at the third node N-CQ, and may be referred to as a third node control circuit. The sixth circuit S106 may include a first transistor T61, a second transistor T62, and a third transistor T63.

The first transistor T61 and the second transistor T62 may be connected to each other in series, and the first transistor T61 and the second transistor T62 may have a dual gate structure. The first transistor T61 and the second transistor T62 may be connected to each other between the first input terminal IN4 and the third node N-CQ. Alternatively, a gate electrode of the first transistor T61 and a gate electrode of the second transistor T62 are all connected to the first input terminal IN1. The first transistor T61 and the second transistor T62 may transmit the second high voltage VDD2 to the third node N-CQ in response to the gate-on voltages (for example, a logic-high level) of the first carry signal CR[N−1].

The third transistor T63 may be connected between the third node N-CQ and the third input terminal IN3. In addition, a gate electrode of the third transistor T63 may be connected to the second input terminal IN2. The third transistor T63 may transmit the first high voltage VDD1 to the third node N-CQ in response to the gate-on voltages (for example, a logic-high level) of the third carry signal CR[N+1].

The seventh circuit S107 may include a transistor T71. The transistor T71 may be connected between the first input terminal IN3 and the third node N-CQ. A gate electrode of the transistor T71 may be connected to the fourth node N-B. The transistor T71 may supply the first high voltage VDD1 to the third node N-CQ, in response to the voltage at the fourth node N-B.

The eighth circuit S108 may include a first transistor T81 and a second transistor T82.

The first transistor T81 and the second transistor T82 may be connected to each other in series, and the first transistor T81 and the second transistor T82 may be connected between the third node N-CQ and the fifth input terminal IN5. Alternatively, a gate electrode of the first transistor T81 and a gate electrode of the second transistor T82 are all connected to the second node QB. The first transistor T81 and the second transistor T82 may transmit the first low voltage VSS1 to the third node N-CQ in response to the voltage at the second node QB. Accordingly, the eighth circuit S108 may be referred to as a third node stabilization circuit.

The ninth circuit S109 may include a plurality of output circuits S109s.

According to some embodiments of the present disclosure, because one stage ST[N] outputs six scan signals, the ninth circuit S109 may include six output circuits S109s. In FIG. 6B, a total of two output circuits, which are the first output circuit and the last output circuit (for example, the sixth output circuit), are illustrated.

Each of the output circuits S109s may include a first transistor T91, a second transistor T92, a third transistor T93, and a capacitor C9. Hereinafter, the first output circuit S109s will be described. Accordingly, because remaining output circuits S109s substantially include components the same as components of the first output circuit S109s, the duplication thereof will be omitted.

The first transistor T91 may be connected between the first clock terminal CIN1 and the first output terminal OUT1. A gate electrode of the first transistor T91 may be connected to the divided node Q-1. The second transistor T92 may be connected between the first node Q-C and the divided Q-1. A gate electrode of the second transistor T92 may be connected to the third node N-CQ. The second transistor T92 may connect the first node Q-C to the divided node Q-1, or disconnect the first node Q-C from the divided node Q-1, in response to the voltage at the third node N-CQ.

The operation of the first transistor T91 may be controlled in response to the voltage at the divided node Q-1. When the first transistor T91 is turned on, a logic-high level voltage of the scan signal SS1[N] may be transmitted to the first output terminal OUT1.

According to some embodiments of the present disclosure, the transistor T71 may be turned on at the timing in which the fourth node N-B is boosted, so the first high voltage VDD1 may be transmitted to the third node N-CQ. The voltage at the first node Q-C may be higher than the first high voltage VDD1 at the third node N-CQ, at the timing in which the fourth node N-B is boosted. Accordingly, the second transistor T92 may be turned off. The second transistor T92 may disconnect the first node Q-C from the divided node Q-1, in response to the voltage at the third node N-CQ.

While signals are output to the first to sixth output terminals OUT1, OUT2, OUT3, OUT4, OUT5, and OUT6, the first node Q-C may be electrically disconnected from the divided node Q-1, and even the divided nodes Q-1 to Q-6 may be electrically disconnected from each other. Accordingly, even if the voltage at the divided node Q-1 is coupled and thus changed in response to the signal output to the first output terminal OUT1, any influence is not exerted on remaining nodes. For example, the remaining nodes may be remaining divided nodes other than the divided node Q-1 among the first node Q-C and the divided nodes Q-1 to Q-6. Accordingly, a stripe failure resulting from the difference in brightness between wires may be removed or reduced

According to some embodiments of the present disclosure, when the second low voltage VSS2 is transmitted to the first node Q-C in response to the gate-on voltage of the third carry signal CR[N+1], the voltage at the first node Q-C may be lower than the voltage at the third node N-CQ. In this case, the second transistor T92 is turned on to connect the first node Q-C to the divided node Q-1, and the divided node Q-1 may be discharged.

The third transistor T93 may be connected between the first output terminal OUT1 and the fifth output terminal IN5. A gate electrode of the third transistor T93 may be connected to the second node QB. The operation of the third transistor T93 may be controlled in response to the voltage at the second node QB. When the third transistor T93 is turned on, the first low voltage VSS1 may be transmitted to the first output terminal OUT1.

The capacitor C9 is connected to the divided node Q-1 and the fourth node N-B. The capacitor C9 may increase (boost up) the voltage at the divided node Q-1 to correspond to the increase in voltage at the fourth node N-B. When the voltage at the divided node Q-1 is boosted up, the scan signal SS1[N] having the high voltage may be output without being distorted.

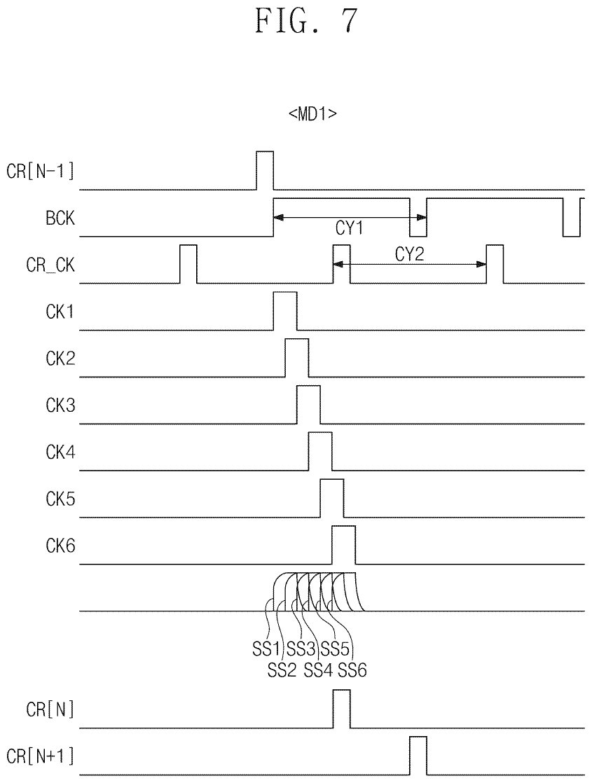

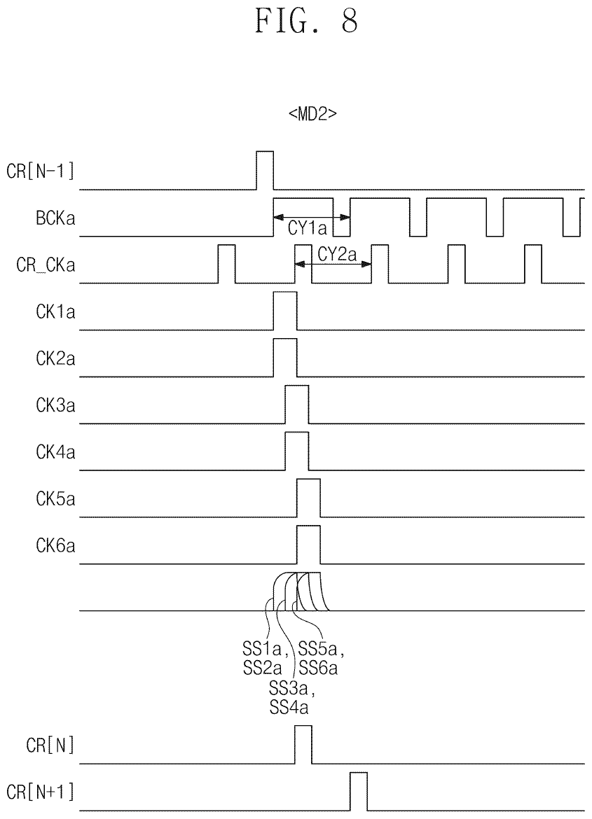

FIG. 7 is a timing diagram to describe the operation of a stage in a first mode MD1 according to some embodiments of the present disclosure. FIG. 8 is a timing diagram of a plurality of clock signals to describe the operation of a stage in a second mode MD2 according to some embodiments of the present disclosure.

Referring to FIGS. 1, 7, and 8, the display panel DP may selectively operate in the first mode MD1 or the second mode MD2. For example, the first mode MD1 may be a typical driving mode in which driving is made at a first frequency, and the second mode MD2 may be a higher-frequency driving mode in which driving is made at a second frequency higher than the first frequency. For example, the first frequency may be 240 Hz, and the second frequency may be 480 Hz. However, the first frequency and the second frequency described above are provided only for the illustrative purpose. For example, the first frequency and the second frequency are not specifically limited to the above examples.

Referring to FIG. 7, the first carry signal CR[N−1], the second carry signal CR[N], the third carry signal CR[N+1], the boost clock signal BCK, the carry clock signal CR_CK, and first to sixth clock signals CK1, CK2, CK3, CK4, CK5, and CK6, in the first mode MD1 are illustrated.

Referring to FIG. 8, the first carry signal CR[N−1], the second carry signal CR[N], the third carry signal CR[N+1], a boost clock signal BCKa, a carry clock signal CR_CKa, and first to sixth clock signals CK1a, CK2a, CK3a, CK4a, CK5a, and CK6a, in the second mode MD2 are illustrated.

Referring to FIGS. 7 and 8, a cycle CY1 of the boost clock signal BCK in the first mode MD1 may be longer than a cycle CY1a of the boost clock signal BCKa in the second mode MD2. For example, the cycle CY1 may be twice the cycle CY1a. In addition, a cycle CY2 of the carry clock signal CR_CK in the first mode MD1 may be longer than a cycle CY2a of the carry clock signal CR_CKa in the second mode MD2. For example, the cycle CY2 may be twice the cycle CY2a. In other words, the cycle of the clocks may be reduced in the second mode MD2.

According to some embodiments of the present disclosure, at least some of a plurality of scan wires may be simultaneously driven (for example, activated) for lower-power driving or higher-power driving. For example, two scan wires may be simultaneously driven, and the second mode MD2 may be referred to a dual line gate driving mode. According to some embodiments of the present disclosure, the first mode MD1 may be a higher resolution mode, and the second mode MD2 may be a higher scanning rate mode.

The first to sixth clock signals CK1a, CK2a, CK3a, CK4a, CK5a, and CK6a may be out of phase with each other in the first mode MD1. In other words, the first to sixth clock signals CK1, CK2, CK3, CK4, CK5, and CK6 may have waveforms shifted by a specific distance. Accordingly, the first to sixth scan signals SS1, SS2, SS3, SS4, SS5, and SS6 output in synchronization of the first to sixth clock signals CK1, CK2, CK3, CK4, CK5, and CK6 may be out of phase with each other. The first to sixth scan signals SS1, SS2, SS3, SS4, SS5, and SS6 may be referred to as first mode scan signals.

The first to sixth scan signals SS1, SS2, SS3, SS4, SS5, and SS6 may be the first scan signals (or referred to as “first-type scan signals”) applied through the first output wires SCLs (see FIG. 5). Alternatively, the first to sixth scan signals SS1, SS2, SS3, SS4, SS5, and SS6 may be the second scan signals (or referred to as “second-type scan signals”) applied through the second output wires SSLs (see FIG. 5).

Some clock signals among of the first to sixth clock signals CK1a, CK2a, CK3a, CK4a, CK5a, and CK6a may be in phase with each other in the second mode MD2. For example, the first clock signal CK1a and the second clock signal CK2a may have the same waveform. The third clock signal CK3a may have a waveform shifted by a specific time from the first clock signal CK1a, and the third clock signal CK3a and the fourth clock signal CK4a may have the same waveform. Accordingly, the fifth clock signal CK5a and the sixth clock signal CK6a may have the same waveform.

Accordingly, some the first to sixth scan signals SS1a, SS2a, SS3a, SS4a, SS5a, and SS6a output in synchronization of the first to sixth clock signals CK1a, CK2a, CK3a, CK4a, CK5a, and CK6a in the second mode MD2 may have waveforms which are in phase with each other. For example, the first scan signal SS1a and the second scan signal SS2a may have waveforms overlapped with each other and substantially the same as each other. In this case, the data voltage DS (see FIG. 6) may be simultaneously applied to pixels in one row, which receive the first scan signal SS1a and pixels in one row, which receives the second scan signal SS2a, in the second mode MD2.

For example, the third scan signal SS3a and the fourth scan signal SS4a may have waveforms superposed with each other and substantially the same as each other. The fifth scan signal SS5a and the second scan signal SS6a may have waveforms overlapped with each other and substantially the same as each other. The first to sixth scan signals SS1a, SS2a, SS3a, SS4a, SS5a, and SS6a may be referred to as second mode scan signals.

The first to sixth scan signals SS1a, SS2a, SS3a, SS4a, SS5a, and SS6a may be the first scan signals (or referred to as “first-type scan signals”) applied through the first output wires SCLs (see FIG. 5). Alternatively, the first to sixth scan signals SS1a, SS2a, SS3a, SS4a, SS5a, and SS6a may be the second scan signals (or referred to as “second-type scan signals) applied through the second output wires SSLs (see FIG. 5).

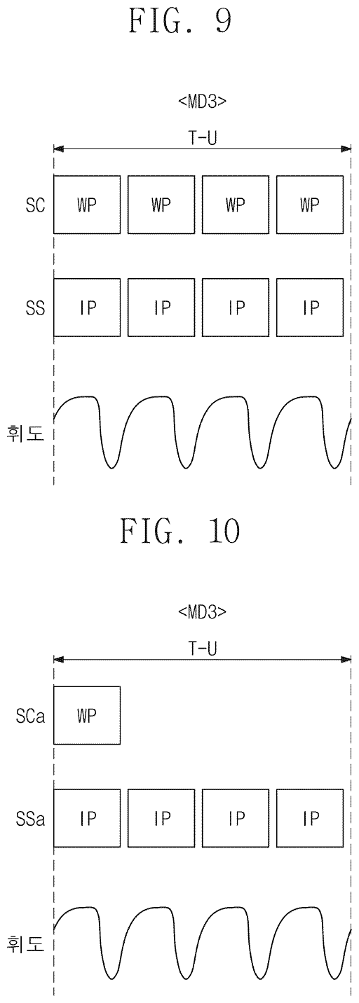

FIG. 9 is a view illustrating an active state and the change in brightness of a first scan signal SC and a second scan signal SS according to some embodiments of the present disclosure. FIG. 10 is a view illustrating an active stage and the change in brightness of a first scan signal SCa and a second scan signal SSa according to some embodiments of the present disclosure.

According to some embodiments of the present disclosure, the first scan signal SC or the first scan signal SCa may be a signal applied through the i-th first output wire SCLi illustrated in FIG. 4, and the second scan signal SS or the second signal SSa may be a signal applied through the i-th second output wire SSLi illustrated in FIG. 4.

Referring to FIGS. 1, 9, and 10, the display panel DP may operate in a mode (hereinafter, a third mode) in which driving is made at a variable frame frequency. For example, the variable frame frequency may be varied while ranging from 1 Hz to 240 Hz, but embodiments according to the present disclosure are not limited thereto. FIG. 9 illustrates the first scan signal SC, the second scan signal SS, and the brightness of the display panel DP, when driving is made at the frequency of 240 Hz. FIG. 10 illustrates the first scan signal SCa, the second scan signal SSa, and the brightness of the display panel DP when driving is made at the frequency of 60 Hz.

Referring to FIGS. 9 and 10, when the display panel DP is driven at the frequency of 240 Hz, the first scan signal SC may include four write cycle periods WP and the second scan signal SS may include four initialization cycle periods IP for the unit time T-U. In addition, when the display panel DP is driven at the frequency of 60 Hz, the first scan signal SCa may include one write cycle period WPa and the second scan signal SSa may include four initialization cycle periods IP, for the unit time T-U.

The first scan signal SC or SCa may have waveforms alternately repeated in a logic-high level and a logic-low level for the write cycle period WP or WPa, and may have a logic-low level for remaining periods except for the write cycle period WP or WPa. In addition, the second scan signal SS or SSa may have waveforms alternately repeated in a logic-high level and a logic-low level for the initialization cycle periods IP.

Referring to FIG. 5, the plurality of first stages SC-ST1, SC-ST2, and SC-ST3 of the first scan driving circuit SCD to generate the first scan signal SC or SCa may be separated from the plurality of second stages SS-ST1, SS-ST2, and SS-ST3 of the second scan driving circuit SSD to generate the second scan signal SS or SSa. Accordingly, the operation of the first scan signal SC or SCa may be separated from the operation of the second scan signal SS or SSa. Accordingly, the number of the initialization cycle periods IP may be adjusted within the unit time T-U, regardless of the operating frequency of the display panel DP. In this case, the difference between the optical waveforms, which result from the operating frequency of the display panel DP, may be reduced. Accordingly, the difference in brightness, which results from the operating frequency of the display panel DP, may be relatively reduced. In other words, the image display quality of the display panel DP may be relatively improved.

The driving modes described with reference to FIGS. 7, 8, 9, and 10 may be applied to the display panel DP through various combinations of the driving modes. For example, according to some embodiments of the present disclosure, the display panel DP may operate in any one of the first mode MD1, the second mode MD2, and a third mode MD3. The first mode MD1 may correspond to a mode in which driving is made at the frequency of 240 Hz from the third mode MD3. For example, according to some embodiments of the present disclosure, the display panel DP may operate in any one of the first mode MD1 and a third mode MD3. In this case, the first mode MD1 may be a general driving mode in which driving is made at a constant frequency, and the third mode MD3 may be a variable driving mode in which driving is made at a variable frequency. Alternatively, according to some embodiments of the present disclosure, the display panel DP may operate in any one of the first mode MD1 and the second mode MD2. Alternatively, according to some embodiments of the present disclosure, the display panel DP may operate only in the first mode MD1. Alternatively, according to some embodiments of the present disclosure, the display panel DP may operate only in the third mode MD3.

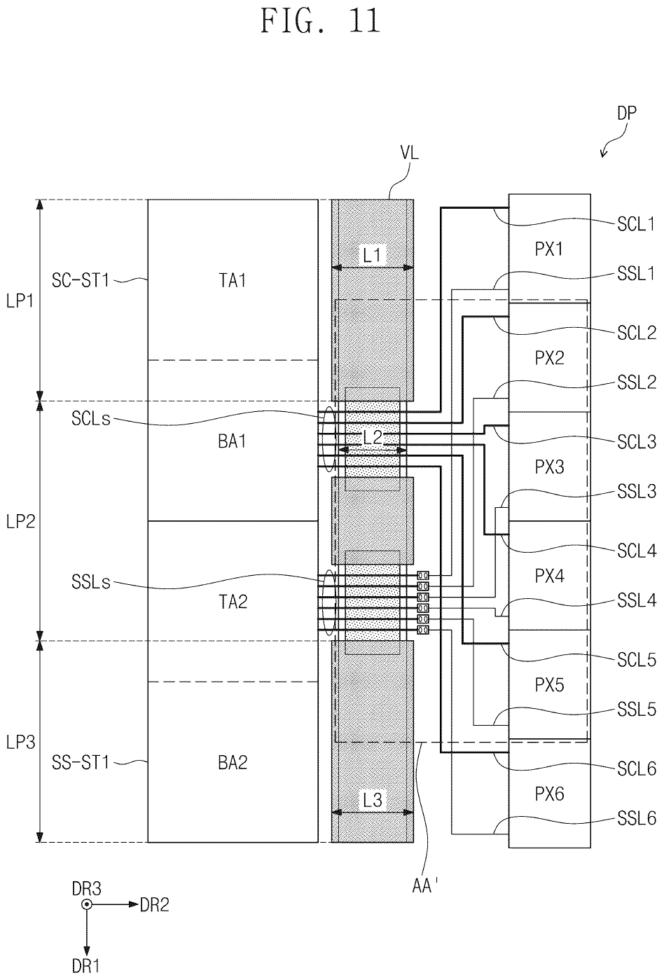

FIG. 11 is a plan view illustrating a portion of the display panel DP according to some embodiments of the present disclosure.

FIG. 11 illustrates one first stage SC-ST1, one second stage SS-ST1, six first output wires SCLs, six second output wires SSLs, and six pixels PX (see FIG. 3) included in the display panel DP. Hereinafter, one first stage SC-ST1 will be referred to as the first stage SC-ST1, and one second stage SS-ST1 will be referred to as the second stage SS-ST1.

Referring to FIG. 11, the display panel DP may include the first stage SC-ST1, the second stage SS-ST1, the first output wires SCLs, the second output wires SSLs, a voltage wire VL, and first to sixth pixels PX1 to PX6.

The first stage SC-ST1 may include a first upper end region TA1 and a first lower end region BA1. The first upper end region TA1 and the first lower end region BA2 may be adjacent to each other in the first direction DR1. When viewed in a plan view, the first upper end region TA1 may be positioned on the first lower end region BA1.

The second stage SS-ST1 may include a second upper end region TA2 and a second lower end region BA2. The second upper end region TA2 and the second lower end region BA2 may be adjacent to each other in the first direction DR1. When viewed in a plan view, the second upper end region TA2 may be positioned on the second lower end region BA2.

The first output wires SCLs may include a (1-1)-th output wire SCL1, a (1-2)-th output wire SCL2, a (1-3)-th output wire SCL3, a (1-4)-th output wire SCL4, a (1-5)-th output wire SCL5, and a (1-6)-th output wire SCL6. The first output wires SCLs may be electrically connected to the first stage SC-ST1. The first output wires SCLs may extend from the first lower end region BA1 of the first stage SC-ST1. For example, when the number of the output wires SCLs extending from the first stage SC-ST1 is six, all six first output wires SCLs may extend from the first lower end region BA1 of the first stage SC-ST1.

The second output wires SSLs may include a (2-1)-th output wire SSL1, a (2-2)-th output wire SSL2, a (2-3)-th SSL3, a (2-4)-th output wire SSL4, a (2-5)-th output wire SSL5, and a (2-6)-th output wire SSL6. The second output wires SSLs may be electrically connected to the second stage SS-ST1. The second output wires SSLs may extend from the second upper end region TA2 of the second stage SS-ST1. For example, when the number of the output wires SSLs extending from the second stage SS-ST1 is six, all six second output wires SSLs may extend from the second upper end region TA2 of the second stage SS-ST1.

The first output wires SCLs and the second output wires SSLs extend from the first lower end region BA1 of the first stage SC-ST1 and the second upper end region TA2 of the second stage SS-ST1, respectively, thereby relatively reducing the path of the first output wires SCLs and the second output wires SSLs for electrical connection with the pixels PX (see FIG. 3). For example, when six first output wires SCLs and six second output wires SSLs are electrically connected to six pixels PX (see FIG. 3), the output wires SCLs and SSLs extend from regions adjacent to intermediate points of six pixels PX (see FIG. 3) arranged in the first direction DR, thereby relatively reducing the lengths of the output wires SCLs and SSLs connected to the six pixels PX (see FIG. 3). Accordingly, as the areas or the widths occupied by the first output wires SCLs and the second output wires SSLs are relatively reduced, the width of the non-display region NDA (see FIG. 3) of the display panel DP may be relatively reduced.

The voltage wire VL may extend in the first direction DR1, and may be interposed between the first stage SC-ST1 and the second stage SS-ST1, and the first to sixth pixels PX1 to PX6. The voltage wire VL may be electrically connected to the fifth input terminal IN5 illustrated in FIG. 6B to receive the first low voltage VSS1. However, this is provided only for the illustrative purpose, and the voltage wire VL is not limited thereto.

According to some embodiments of the present disclosure, the first output wires SCLs extending from the first lower end region BA1 of the first stage SC-ST1 and the second output wires SSLs extending from the second upper end region TA2 of the second stage SS-ST1 may be insulated from the voltage wire VL while crossing the voltage wire VL and extending in the second direction DR2.

The voltage wire VL may include a first wire part LP1, a second wire part LP2, and a third wire part LP3. In this case, a portion of the second wire part LP2 of the voltage wire VL may be a portion at which the voltage wire VL crosses the first output wires SCLs and the second output wires SSLs. When viewed in a plan view, at least a portion of the second wire part LP2 of the voltage wire VL may be overlapped with the first output wires SCLs and the second output wires SSLs.

The first wire part LP1, the second wire part LP2, and the third wire part LP3 may be adjacent to each other in the first direction DR1. For example, when viewed in a plan view, the first wire part LP1, the second wire part LP2, and the third wire part LP3 may be sequentially adjacent to each other in the first direction DR1.

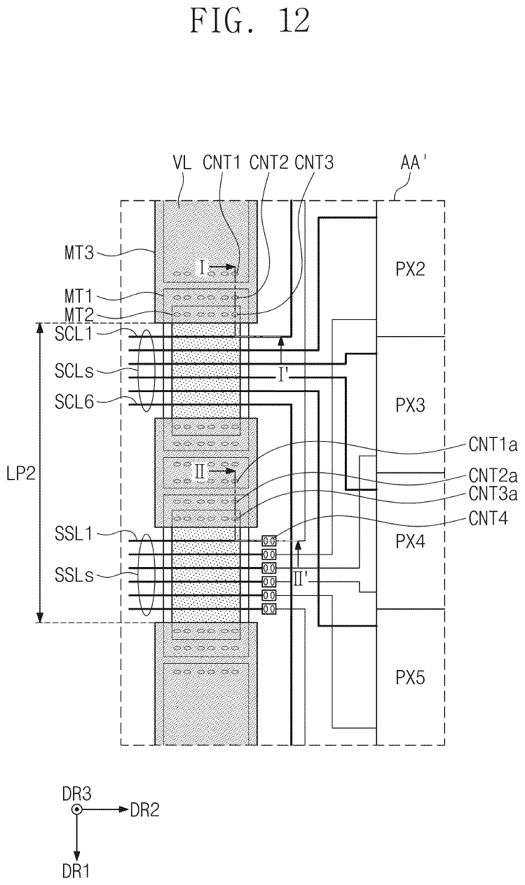

According to some embodiments of the present disclosure, as the first output wires SCLs and the second output wires SSLs extend only in the first lower end region BA1 of the first stage SC-ST1 and the second upper end region TA2 of the second stage SS-ST1, the first output wires SCLs and the second output wires SSLs may be overlapped with the portion of the second wire part LP2 of the voltage wire VL while 1 crossing the portion of the second wire part LP2 of the voltage wire VL, instead of the entire portion of the voltage wire VL. For example, when the first output wires SCLs are located to be adjacent to each other, and when the second output wires SSLs are located to be adjacent to each other, an area, in which a third wire pattern MT3 (see FIG. 12) of the voltage wire VL is omitted, may be minimized. Accordingly, as compared to when the first output wires SCLs and the second output wires SSLs are overlapped with the entire portion of the voltage wire VL while crossing the entire portion of the voltage wire VL, a ratio of exerting an influence on the resistance of the voltage wire VL may be relatively reduced.

The pixels PX (see FIG. 3) may include a first pixel PX1, a second pixel PX2, a third pixel PX3, a fourth pixel PX4, a fifth pixel PX5, and a sixth pixel PX6. The pixels PX (see FIG. 3) may be arranged in the first direction DR1, in order of the first pixel PX1, the second pixel PX2, the third pixel PX3, the fourth pixel PX4, the fifth pixel PX5, and the sixth pixel PX6

The first pixel PX1, the second pixel PX2, and the third pixel PX3 may be spaced apart from the first stage SC-ST1 in the second direction DR2. The first pixel PX1 may be electrically connected to the (1-1)-th output wire SCL1 and the (2-1) output wire SSL1. The second pixel PX2 may be electrically connected to the (1-2)-th output wire SCL2 and the (2-2)-th output wire SSL2. The third pixel PX3 may be electrically connected to the (1-3)-th output wire SCL3 and the (2-3)-th output wire SSL3.

The fourth pixel PX4, the fifth pixel PX5, and the sixth pixel PX6 may be spaced apart from the second stage SS-ST1 in the second direction DR2. The fourth pixel PX4 may be electrically connected to the (1-4)-th output wire SCL4 and the (2-4)-th output wire SSL4. The fifth pixel PX5 may be electrically connected to the (1-5)-th output wire SCL5 and the (2-5)-th output wire SSL5. The sixth pixel PX6 may be electrically connected to the (1-6)-th output wire SCL6 and the (2-6)-th output wire SSL6.

The first scan signals output from the first stage SC-ST1 may be transmitted to the first to sixth pixels PX1 to PX6 through the first output wires SCLs. The second scan signals output from the second stage SS-ST1 may be transmitted to the first to sixth pixels PX1 to PX6 through the second output wires SSLs. Accordingly, each of the first to sixth pixels PX1 to PX6 may receive a relevant one first scan signal and a relevant one second signal.

FIG. 12 is an enlarged view illustrating region AA′ illustrated in FIG. 11 according to some embodiments of the present disclosure. The region AA′ illustrated in FIG. 11 shows the structure obtained by enlarging the second wire part LP2 of the voltage wire VL.

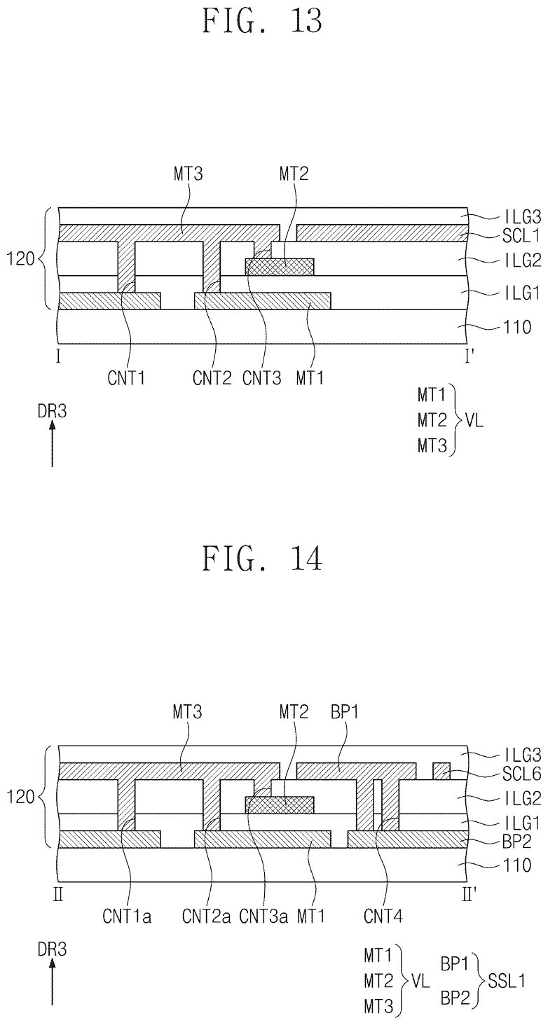

Referring to FIG. 12, the voltage wire VL may have a multi-layer structure including at least two layers. The voltage wire VL may include a first wire pattern MT1, a second wire pattern MT2, and a third wire pattern MT3. Referring to FIGS. 13 and 14, the first wire pattern MT1 may be located at the lower most layer, and the second wire pattern MT2 may be located at a layer different from the layer for the first wire pattern MT1, and at an intermediate layer between layers for the first wire pattern MT1 and the third wire pattern MT3. The third wire pattern MT3 may be located at a layer different from layers for the first wire pattern MT1 and the second wire pattern MT2, and may be located at the upper most layer. Accordingly, the first wire pattern MT1, the second wire pattern MT2, and the third wire pattern MT3 may be located at mutually different layers.

The first wire pattern MT1, the second wire pattern MT2, and the third wire pattern MT3 may be electrically connected to each other. The first wire pattern MT1 and the third wire pattern MT3 may be electrically connected to each other through a first contact hole CNT1 or CNT1a and a second contact hole CNT2 or CNT2a. The second wire pattern MT2 and the third wire pattern MT3 may be electrically connected to each other through a third contact hole CNT3 or CNT3a. The first contact hole CNT1 or CNT1a, the second contact hole CNT2 or CNT2a, and the third contact hole CNT3 or CNT3a may be provided in the form of one contact hole or in the form of at least two contact holes.

When viewed a plan view, the first output wires SCLs and the second output wires SSLs may be overlapped with at least a portion of the second wire pattern MT2 and the first wire pattern MT1 of the voltage wire VL, while crossing the voltage wire VL. The first output wires SCLs and the second output wires SSLs may not be overlapped with the third wire pattern MT3 of the voltage wire VL, and may be spaced apart from each other in the first direction DR1.

The third wire pattern MT3 may not be located in a region, which are overlapped with the first output wires SCLs and the second output wires SSLs, of the second wire part LP2 of the voltage wire VL. Accordingly, a minimum width L1 of the first wire part LP1 of the voltage wire VL may be greater than a minimum width L2 of the second wire part LP2.

FIG. 13 is a cross-sectional view of the display panel DP taken along line I-I′ of FIG. 12 according to some embodiments of the present disclosure. FIG. 14 is a cross-sectional view of the display panel DP taken along line II-II′ of FIG. 12 according to some embodiments of the present disclosure.

Referring to FIGS. 13, and 14, the display panel DP may further include a base layer 110 and a circuit layer 120. FIGS. 13 and 14 merely illustrate some components of the display panel DP, and the display panel DP may further include a light emitting element layer including the light emitting element ED (see FIG. 4) and an encapsulating layer to cover the same.

The base layer 110 may be a member to provide a base surface for arranging the circuit layer 120. The base layer 110 may have a multi-layer structure or a single-layer structure. The base layer 110 may be a glass substrate, a metal substrate, a silicon substrate, or a polymer substrate, and embodiments according to the present disclosure are not limited thereto specifically.

The circuit layer 120 may be located on the base layer 110. The circuit layer 120 may include a first intermediate insulating layer ILG1, a second intermediate insulating layer ILG2, and a third intermediate insulating layer ILG3. Each of the first intermediate insulating layer ILG1, the second intermediate insulating layer ILG2, and the third intermediate insulating layer ILG3 may include at least one insulating layer, and each of the at least one insulating layer may include an inorganic insulating layer or an organic insulating layer.

Referring to FIG. 13, the first wire pattern MT1, the second wire pattern MT2, the third wire pattern MT3, and the (1-1)-th output wire SCL1 included in the circuit layer 120 are illustrated.

The first wire pattern MT1 may be located on the base layer 110. The first intermediate insulating layer ILG1 may be located on the base layer 110, to cover the first wire pattern MT1. The second wire pattern MT2 may be located on the first intermediate insulating layer ILG1. The second intermediate insulating layer ILG2 may be located on the first intermediate insulating layer ILG1 to cover the second wire pattern MT2. The third wire pattern MT3 and the (1-1)-th output wire SCL1 may be located on the second intermediate insulating layer ILG2. The third intermediate insulating layer ILG3 may be located on the second intermediate insulating layer ILG2 to cover the third wire pattern MT3 and the (1-1)-th output wire SCL1

The third wire pattern MT3 may be electrically connected to the first wire pattern MT1 through the first to second contact holes CNT1 and CNT2 formed through the first to second intermediate insulating layers ILG1 and ILG2. The third wire pattern MT3 may be electrically connected to the second wire pattern MT2 through the third contact hole CNT3 formed through the second intermediate insulating layer ILG2.

According to some embodiments of the present disclosure, the (1-1)-th output wire SCL1 may be located at the same layer as the third wire pattern MT3. The (1-1)-th output wire SCL1 may be located at different layers from the first wire pattern MT1 and the second wire pattern MT2.

Although FIG. 13 illustrates a cross-sectional view of a portion of the (1-1)-th output wire SCL1, remaining first output wires SCLs may be substantially same as the (1-1)-th output wire SCL1, so the details of the remaining first output wires SCLs will be omitted. In addition, although FIG. 13 illustrates the first output wires SCLs in a single-layer structure, the first output wires SCLs may have a multi-layer structure.

Referring to FIG. 14, the first wire pattern MT1, the second wire pattern MT2, the third wire pattern MT3, a (2-1)-th output wire SSL1, and a (1-6)-th output wire SCL6 included in the circuit layer 120 are illustrated.

The structure of the first wire pattern MT1, the second wire pattern MT2, and the third wire pattern MT3 in FIG. 14 may be the same that illustrated in FIG. 13. Accordingly, the details thereof will be omitted, and the following description will be made while focusing on the difference between FIG. 13 and FIG. 14.

According to some embodiments of the present disclosure, the (2-1)-th output wire SSL1 may include a first bridge part BP1 and a second bridge part BP2.

The first bridge part BP1 may be located on the second intermediate insulating layer ILG2, and the third intermediate insulating layer ILG3 may cover the first bridge part BP1. The first bridge part BP1 may be located at the same layer as that of the third wire pattern MT3.

The second bridge part BP2 may be located on the base layer 110, and the first intermediate insulating layer ILG1 may cover the second bridge part BP2. The second bridge part BP2 may be located at a layer different from the third wire pattern MT3, and may be located at the same layer as the first wire pattern MT1.

The first bridge part BP1 may be electrically connected to the second bridge part BP2 through a fourth contact hole CNT4 formed through the first to second intermediate insulating layers ILG1 and ILG2. Although FIG. 14 illustrates two fourth contact holes CNT4, embodiments according to the present disclosure are not limited thereto. For example, one fourth contact hole CNT4 may be provided, or at least three fourth contact hole CNT4 may be provided. When viewed in a plan view, the first bridge part BP1 may be overlapped with at least a portion of the first wire pattern MT1 and the second wire pattern MT2 of the voltage wire VL, and may be spaced apart from the third wire pattern MT3 of the voltage wire VL. At least a portion of the first bridge part BP1 may be overlapped with the second bridge part BP2, and the second bridge part BP2 may be spaced apart from the first wire pattern MT1 of the voltage wire VL.

The (1-6)-th output wire SCL6 are located at the second intermediate insulating layer ILG2, and the third intermediate insulating layer ILG3 may cover the (1-6)-th output wire SCL6. The (1-6)-th output wire SCL6 may be located at the same layer as that of the third wire pattern MT3 of the voltage wire VL and the first bridge part BP1 of the (2-1) output wire SSL1, and may be spaced apart from the third wire pattern MT3 of the voltage wire VL and the first bridge part BP1 of the (2-1) output wire SSL1.

Although FIG. 14 illustrates a cross-sectional view of a portion of the (2-1)-th output wire SSL1, remaining second output wires SSLs may be substantially same as the (2-1)-th output wire SSL1, so the details of the remaining second output wires SCLs will be omitted. In addition, although FIG. 14 illustrates the second output wires SCLs in a single-layer structure, the first output wires SCLs may have a multi-layer structure. As the first output wires SCLs of FIG. 13, and the second output wires SSLs of FIG. 14 extend at mutually different layer, the output wires SCLs and SSLs may be prevented from being shorted.

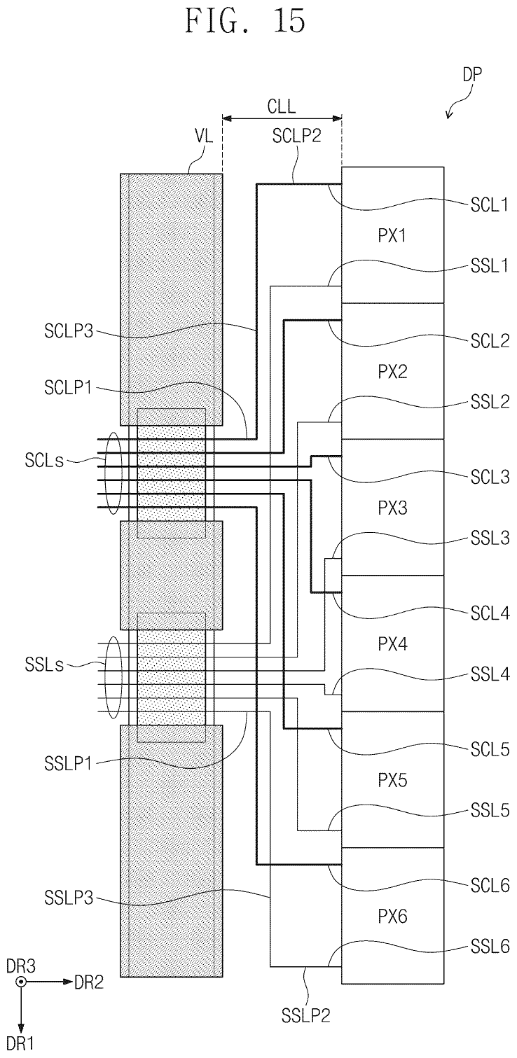

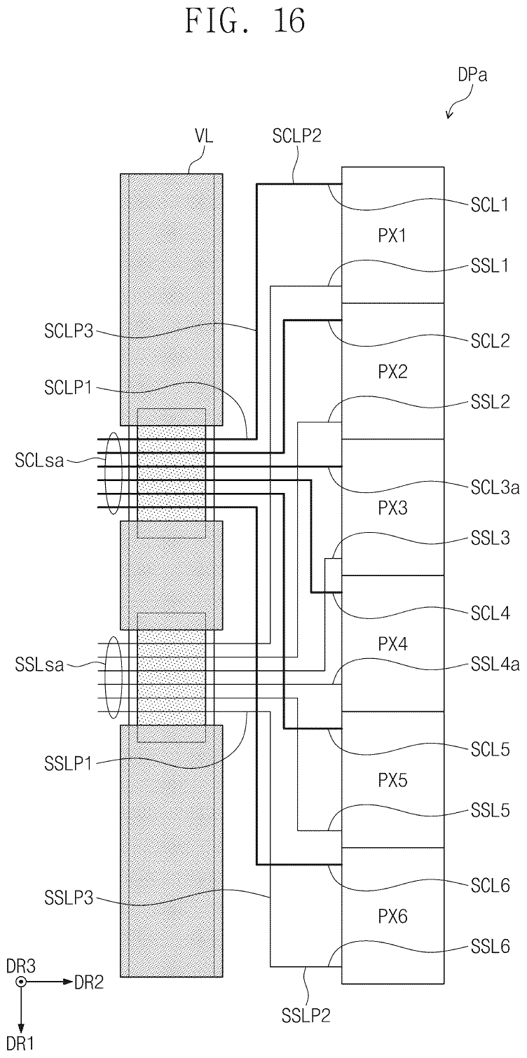

FIG. 15 is a plan view illustrating a portion of the display panel DP according to some embodiments of the present disclosure. FIG. 16 is a plan view illustrating a portion of the display panel DPa according to some embodiments of the present disclosure.

In FIGS. 15 and 16, components the same as components illustrated in FIG. 11 are assigned with the same reference numerals as those in FIG. 11, and the details thereof will be omitted.

Referring to FIGS. 11, 15, and 16, the first output wires SCLs and the second output wires SSLs may cross the voltage wire VL and may be located in the connection wire space CLL. The connection wire space CLL may refer to a space between the voltage wire VL and the first to sixth pixels PX1 to PX6.

Each of the first output wires SCLs may include a first part SCLP1, a second part SCLP2, and a third part SCLP3. The first part SCLP1 of each of the first output wires SCLs may be a part adjacent to the first stage SC-ST1 and extending in the second direction DR2. The second part SCLP2 of each of the first output wires SCLs may be a part adjacent to the first to sixth pixels PX1 to PX6 and extending in the second direction DR2. The third part SCLP3 of each of the first output wires SCLs may be a part to connect the first part SCLP1 and the second part SCLP2.

For example, regarding the (1-1)-th output wire SCL1 of the first output wires SCLs, the first part SCLP1 may a part ranging from a starting point at which the (1-1)-th output wire SCL1 extends from the first stage SC-ST1, to a point at which the (1-1)-th output wire SCL1 is bent at a right angle. The second part SCLP2 may be a part ranging from a point at which the (1-1)-th output wire SCL1 is connected to the pixel PX1 to a point at which the (1-1)-th output wire SCL1 is bent at a right angle. The third part SCLP3 may be a part to connect the first part SCLP1 to the second part SCLP2, that is, a portion, which extends in the first direction DR1, of the (1-1)-th output wire SCL1.

Each of the second output wires SSLs may include a first part SSLP1, a second part SSLP2, and a third part SSLP3. The first part SSLP1 of each of the second output wires SSLs may be a part adjacent to the second stage SS-ST1 and extending in the second direction DR2. The second part SSLP2 of each of the second output wires SSLs may be a part adjacent to the first to sixth pixels PX1 to PX6 and extending in the second direction DR2. The third part SSLP3 of each of the second output wires SSLs may be a part to connect the first part SSLP1 and the second part SSLP2.

For example, regarding the (2-6)-th output wire SSL6 of the second output wires SSLs, the first part SSLP1 may a part ranging from a starting point at which the (2-6)-th output wire SSL6 extends from the second stage SS-ST1, to a point at which the (2-6)-th output wire SSL6 is bent at a right angle. The second part SSLP2 may be a part ranging from a point at which the (2-6)-th output wire SSL6 is connected to the pixel PX6 to a point at which the (2-6)-th output wire SSL6 is bent at a right angle. The third part SSLP3 may be a part to connect the first part SSLP1 to the second part SSLP2, that is, a portion, which extends in the first direction DR1, of the (2-6)-th output wire SSL6.

Referring to FIG. 11, when viewed in a plan view, a half of the first output wires SCLs and the second output wires SSLs may extend from the first stage SC-ST1 and the second stage SS-ST1 and may be bent at a right angle in an opposite direction to the first direction DR1. The remaining half of the first output wires SCLs and the second output wires SSLs may be extend from the first stage SC-ST1 and the second stage SS-ST1 and may be bent at a right angle in the first direction DR1. For example, three first output wires SCLs and three second output wires SSLs, which are positioned at an upper portion, among the first output wires SCLs and the second output wires SSLs may extend from the first stage SC-ST1 and the second stage SS-ST1 and may be bent at a right angle in an opposite direction to the first direction DR1, and the remaining three first output wires SCLs and the remaining three second output wires SSLs may be extend from the first stage SC-ST1 and the second stage SS-ST1 and may be bent at a right angle in the first direction DR1. Accordingly, the number of the first output wires SCLs and the second output wires SSLs, which cross each other in the connection wire space CLL, may be relatively reduced. Accordingly, as the area or the width occupied by the first output wires SCLs and the second output wires SSLs is relatively reduced, the area or the width of the connection wire space CLL may be relatively reduced. Accordingly, the width of the non-display region NDA (see FIG. 3) of the display panel DP may be relatively reduced.

Referring to FIGS. 11 and 15, when viewed in a plan view, the (1-1)-th output wire SCL1, the (1-2)-th output wire SCL2, and the (1-3)-th output wire SCL3 may extend from the first stage SC-ST1 and may be bent at a right angle in the opposite direction to the first direction DR1. In each of the (1-1)-th output wire SCL1, the (1-2)-th output wire SCL2, and the (1-3)-th output wire SCL3, the first part SCLP1 may be positioned under the second part SCLP2. The (1-4)-th output wire SCL4, the (1-5)-th output wire SCL5, and the (1-6)-th output wire SCL6 may extend from the first stage SC-ST1 and may be bent at a right angle in the first direction DR1. In each of the (1-4)-th output wire SCL4, the (1-5)-th output wire SCL5, and the (1-6)-th output wire SCL6, the first part SCLP1 may be positioned above the second part SCLP2.

When viewed in a plan view, the (2-1)-th output wire SSL1, the (2-2)-th output wire SSL2, and the (2-3)-th output wire SSL3 may extend from the second stage SS-ST1 and may be bent at a right angle in the opposite direction to the first direction DR1. In each of the (2-1)-th output wire SSL1, the (2-2)-th output wire SSL2, and the (2-3)-th output wire SSL3, the first part SSLP1 may be positioned under the second part SSLP2. The (2-4)-th output wire SSL4, the (2-5)-th output wire SSL5, and the (2-6)-th output wire SSL6 may extend from the first stage SS-ST1 and may be bent at a right angle in the first direction DR1. In each of the (2-4)-th output wire SSL4, the (2-5)-th output wire SSL5, and the (2-6)-th output wire SSL6, the first part SSLP1 may be positioned above the second part SSLP2.

Referring to FIG. 16, as compared to FIG. 15, in a (1-3)-th output wire SCL3a and a (2-4)-th output wire SSL4a, the first parts SCLP1a and SSLP1a, second parts SCLP2a and SSLP2a, and third parts SCLP3a and SSLP3a may be arranged along the same line extending in the second direction. The (1-3)-th output wire SCL3a may straightly extend without being bent to electrically connect the first stage SC-ST1 to the third pixel PX3. The (2-4)-th output wire SSL4a may straightly extend without being bent to electrically connect the second stage SS-ST1 to the fourth pixel PX4. Accordingly, as illustrated in FIG. 15, as the area or the width occupied by the first output wires SCLsa and the second output wires SSLsa is relatively reduced, the area or the width of the connection wire space CLL may be relatively reduced. Accordingly, the width of the non-display region NDA (see FIG. 3) of the display panel DPa may be relatively reduced.

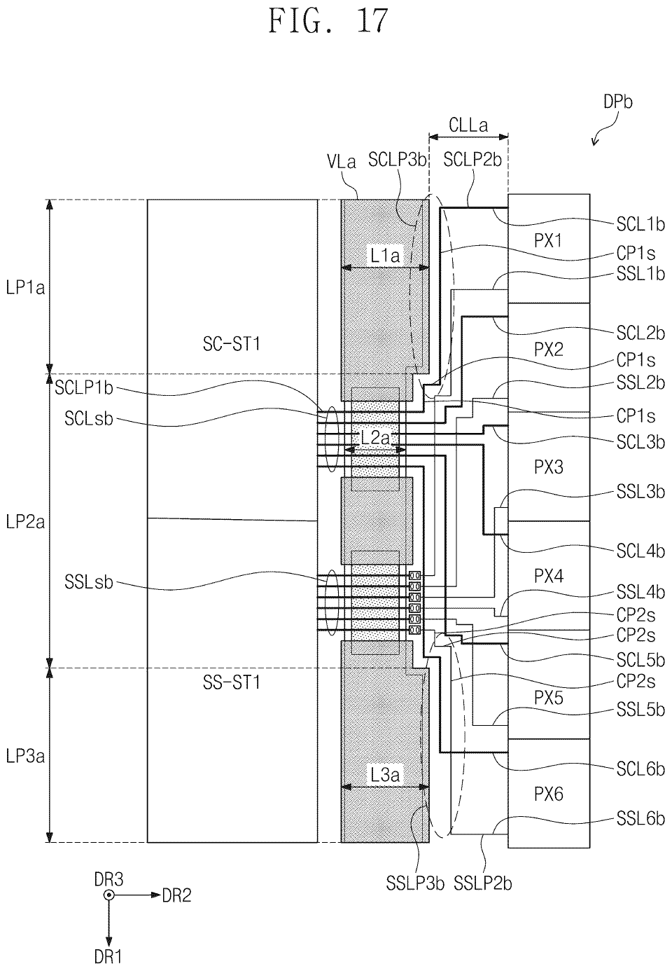

FIG. 17 is a plan view illustrating a portion of a display panel DPb according to some embodiments of the present disclosure.

Referring to FIG. 17, the display panel DPb may include a voltage wire VLa, first output wires SCLsb, and second output wires SSLsb. In FIGS. 17, components the same as components illustrated in FIG. 11 are assigned with the same reference numerals as those in FIG. 11, and the details thereof will be omitted.

A voltage wire VLa may include a first wire part LP1a, a second wire part LP2a, and a third wire part LP3a. According to some embodiments of the present disclosure, a minimum width L1a of a first wire part L13a and a minimum width L3a of a third wire part LP3a may be greater than a minimum width L2a of the second wire part LP2a, when viewed in the second direction DR2. In addition, the minimum width L1a of the first wire part LP1a and the minimum width L3a of the third wire part LP3a in FIG. 17 may be greater than the minimum width L1 of the first wire part LP1 and the minimum width L3 of the third wire part LP3 of FIG. 11. The minimum width L2a of the second wire part LP2a in FIG. 17 may be less than the minimum width L2 of the second wire part LP2 in FIG. 11.

As the minimum width L1a of the first wire part LP1a and the minimum width L3a of the third wire part LP3a are increased, the resistance of a voltage wire VLa may be relatively reduced, and the minimum width L2a of the second wire part LP2a may be reduced by the reduced resistance. As the minimum width L2a of the second wire part LP2a is reduced, the first output wires SCLsb and the second output wires SSLsb may be freely arranged at the center of a connection wire space CLLa having the higher density of the first output wires SCLsb and the second output wires SSLsb. When the output wires SCLsb and SSLsb are freely arranged, the area or the width of the connection wire space CLLa necessary for the arrangement of the output wires SCLsb and SSLsb may be relatively reduced. Accordingly, the non-display region NDA (see FIG. 3) of the display panel DPb may be relatively reduced.

The first output wires SCLsb may include a (1-1)-th output wire SCL1b, a (1-2)-th output wire SCL2b, a (1-3)-th output wire SCL3b, a (1-4)-th output wire SCL4b, a (1-5)-th output wire SCL5b, and a (1-6)-th output wire SCL6b. Each of the first output wires SCLsb may include a first part SCLP1b, a second part SCLP2b, and a third part SCLP3b.

According to some embodiments of the present disclosure, the third part SCLP3b of each of the first output wires SCLsb may include a plurality of connection parts CP1s. As a space is formed due to the change in width of the voltage wire VLa, at least a portion of the plurality of connection parts CP1s of each of the first output wires SCLsb may fill the space while extending in mutually different directions. The third part SCLP3b of the first output wires SCLsb may be bent at a right angle at least two times while filling an empty space, as the minimum width L1a of the first wire part LP1a of the voltage wire VLa is increased, and the minimum width L2a of the second wire part LP2a of the voltage wire VLa is relatively reduced. For example, two portions of the plurality of connection parts CP1s may be extend in the first direction DR1 and a remaining portion of the plurality of connection parts CP1s may extend in the second direction DR2.

The second output wires SSLsb may include a (2-1)-th output wire SSL1b, a (2-2)-th output wire SSL2b, a (2-3)-th output wire SSL3b, a (2-4)-th output wire SSL4b, a (2-5)-th output wire SSL5b, and a (2-6)-th output wire SSL6b. Each of the second output wires SSLsb may include a first part SSLP1b, a second part SSLP2b, and a third part SSLP3b.

According to some embodiments of the present disclosure, the third part SSLP3b of each of the second output wires SSLsb may include a plurality of connection parts CP2s. As a space is formed due to the change in width of the voltage wire VLa, at least a portion of the plurality of connection parts CP2s of each of the second output wires SSLsb may fill the space while extending in mutually different directions. Accordingly, the third part SSLP3b of the second output wires SSLsb may be bent at a right angle at least two times while extending. For example, two portions of the plurality of connection parts CP2s may be extend in the first direction DR1 and a remaining portion of the plurality of connection parts CP2s may extend in the second direction DR2.

Although FIG. 17 illustrates that the third parts SCLP3b and SSLP3b of the remaining first output wires SCLsb except for the (1-3)-th output wire SCL3b and the remaining second output wires SSLsb except for the (2-4)-th output wires SSL4b include the plurality of connection parts CP1s and the plurality of connection parts CP2s, embodiments according to the present disclosure are not limited thereto. Even the third parts SCLP3b and SSLP3b of the (1-3)-th output wire SCL3b and the (2-4)-th output wire SSL4b may include the plurality of connection parts CP1s and the plurality of connection parts CP2s. Only portions of the first output wires SCLsb and the second output wires SSLsb may include the third parts SCLP3b and SSLP3b including the plurality of connection parts CP1s and CP2s.

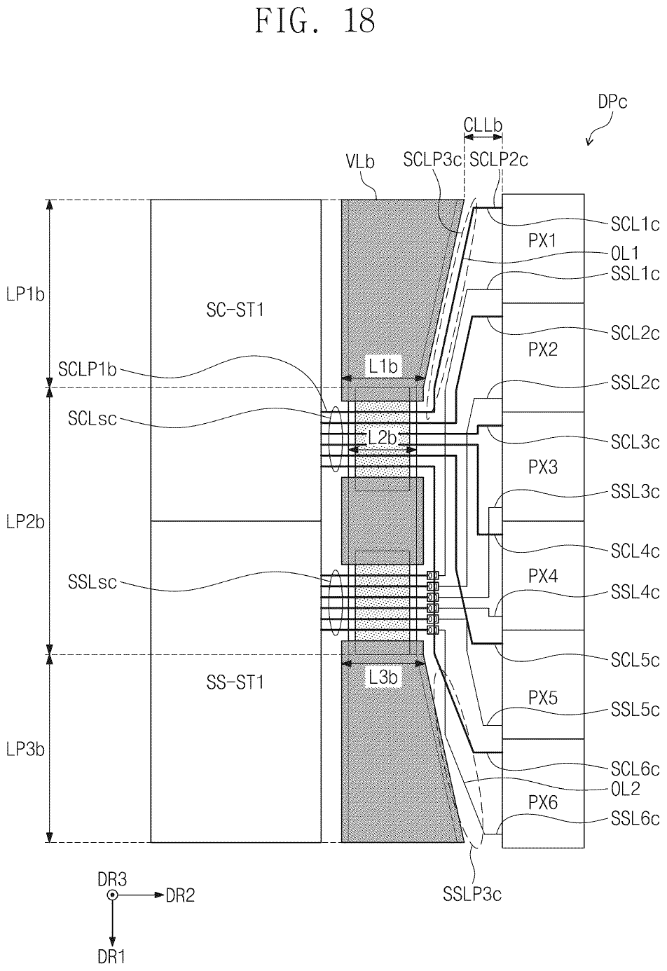

FIG. 18 is a plan view illustrating a portion of a display panel DPc according to some embodiments of the present disclosure. In FIG. 18, components the same as components illustrated in FIG. 11 are assigned with the same reference numerals as those in FIG. 11, and the details thereof will be omitted.

Referring to FIG. 18, the display panel DPc may include a voltage wire VLb, first output wires SCLsc and second output wires SSLsc.

A voltage wire VLb may include a first wire part LP1b, a second wire part LP2b, and a third wire part LP3b. According to some embodiments of the present disclosure, a minimum width L1b of the first wire part LP1b and a minimum width L3b of the third wire part LP3b may be greater than a minimum width L2b of the second wire part LP2b, when viewed in the second direction DR2.

In FIG. 17, the overall sizes of the minimum width L1a of the first wire part LP1a and the minimum width L3a of the third wire part LP3a are increased in the second direction DR2, the first wire part LP1a and the third wire part LP3a may protrude in the second direction DR2 at a right angle with respect to the second wire part LP2a. When compared to FIG. 17, FIG. 18 illustrates that the first wire part LP1b and the third wire part LP3b are gradually enlarged from a connection point with the second wire part LP2b in the second direction DR2, such that the widths of the first wire part LP1b and the third wire part LP3b are greater than minimum widths L1b and L3b corresponding to the first wire part LP1b and the third wire part LP3b. In addition, when compared to the second wire part LP2b, portions of the first wire part LP1b and the third wire part LP3b may protrude obliquely in a direction crossing the first direction DR1 and the second direction DR2.

As the width of the first wire part LP1b and the width of the third wire part LP3b are gradually increased from the corresponding minimum widths L1b and L3b, the resistance of the voltage wire VLb may be relatively reduced, and the minimum width L2b of the second wire part LP2b may be relatively reduced by the reduced resistance. As the minimum width L2b of the second wire part LP2b is reduced, the first output wires SCLsc and the second output wires SSLsc may be freely arranged at the center of a connection wire space CLLb having the higher density of the first output wires SCLsc and the second output wires SSLsc. When the output wires SCLsc and SSLsc are freely arranged, the area or the width of the connection wire space CLLb necessary for the arrangement of the output wires SCLsb and SSLsb may be relatively reduced. Accordingly, the width of the non-display region NDA (see FIG. 3) of the display panel DPc may be relatively reduced.

The first output wires SCLsc may include a (1-1)-th output wire SCL1c, a (1-2)-th output wire SCL2c, a (1-3)-th output wire SCL3c, a (1-4)-th output wire SCL4c, a (1-5)-th output wire SCL5c, and a (1-6)-th output wire SCL6c. Each of the first output wires SCLsc may include a first part SCLP1c, a second part SCLP2c, and a third part SCLP3c.

According to some embodiments of the present disclosure, the third part SCLP3c of the first output wires SCLsc may further include an oblique part OL1 extending in the direction crossing the first direction DR1 and the second direction DR2. As a space is formed due to the change in width of the voltage wire VLb, the third part SCLP3c including the oblique part OL1 of each of the first output wires SCLsc may fill the space while extending obliquely in the direction crossing the first direction DR1 and the second direction DR2.

The second output wires SCLsc may include a (2-1)-th output wire SSL1c, a (2-2)-th output wire SSL2c, a (2-3)-th output wire SSL3c, a (2-4)-th output wire SSL4c, a (2-5)-th output wire SSL5c, and a (2-6)-th output wire SSL6c. Each of the second output wires SSLsc may include a first part SSLP1c, a second part SSLP2c, and a third part SSLP3c.

According to some embodiments of the present disclosure, the third part SSLP3c of each of the second output wires SSLsc may further include an oblique part OL2 extending in a direction crossing the first direction DR1 and the second direction DR2. As a space is formed due to the change in width of the voltage wire VLb, the third part SSLP3c including the oblique part OL2 of each of the second output wires SSLsc may fill the space while extending obliquely in the direction crossing the first direction DR1 and the second direction DR2.

Although FIG. 18 illustrates that the third parts SCLP3c and SSLP3c of the remaining first output wires SCLsc except for the (1-3)-th output wire SCL3c and the remaining second output wires SSLsc except for the (2-4)-th output wires SSL4c include oblique parts OL1 and OL2 extending in the direction crossing the first direction DR1 and the second direction DR2, embodiments according to the present disclosure are not limited thereto. Even the third parts SCLP3c and SSLP3c of the (1-3)-th output wire SCL3c and the (2-4)-th output wire SSL4c may include the oblique parts OL1 and OL2. Only portions of the first output wires SCLsc and the second output wires SSLsc may include the third parts SCLP3c and SSLP3c including the oblique parts OL1 and OL2.

Although aspects of some embodiments of the present disclosure has been described for illustrative purposes, those skilled in the art will appreciate that various modifications, and substitutions are possible, without departing from the scope and spirit of embodiments according to the present disclosure as disclosed in the accompanying claims, and their equivalents. Accordingly, the technical scope of embodiments according to the present disclosure is not limited to the detailed description of this specification, but should be defined by the claims, and their equivalents.

As the first output wires and the second output wires extend from the first lower end region of the first stage and the second upper end region of the second stage, the path of the first output wires and the second output wires may be relatively reduced for the electrical connection with the pixels. As the areas or the widths occupied by the first output wires and the second output wires are relatively reduced, the width of the non-display region of the display panel may be relatively reduced.

While aspects of some embodiments of the present disclosure have been described with reference to embodiments thereof, it will be apparent to those of ordinary skill in the art that various changes and modifications may be made thereto without departing from the spirit and scope of embodiments according to the present disclosure as set forth in the following claims, and their equivalents.

What is claimed is:

1. A display panel comprising:
a first stage including a first upper end region and a first lower end region adjacent to each other in a first direction;
a second stage spaced apart from the first stage in the first direction, and including a second upper end region and a second lower end region adjacent to each other in the first direction;
a plurality of pixels arranged in the first direction, and spaced apart from the first stage and the second stage in a second direction crossing the first direction;
a plurality of first output wires electrically connected to the first stage and the plurality of pixels; and
a plurality of second output wires electrically connected to the second stage and the plurality of pixels, respectively,
wherein the plurality of first output wires extend from the first lower end region of the first stage, and the plurality of second output wires extend from the second upper end region of the second stage.

2. The display panel of claim 1, wherein each of the first stage and the second stage is provided in plurality, and
wherein the plurality of first stages and the plurality of second stages are arranged while crossing each other in the first direction.

3. The display panel of claim 1, wherein the plurality of first output wires include:
a (1-1)-th output wire, a (1-2)-th output wire, a (1-3)-th output wire, a (1-4)-th output wire, a (1-5)-th output wire, and a (1-6)-th output wire, and
wherein the plurality of second output wires include:
a (2-1)-th output wire, a (2-2)-th output wire, a (2-3)-th output wire, a (2-4)-th output wire, a (2-5)-th output wire, and a (2-6)-th output wire.

4. The display panel of claim 3, wherein each of the plurality of first output wires and the plurality of second output wires includes:
a first part adjacent to the first stage and the second stage while extending in the second direction;
a second part adjacent to the plurality of pixels while extending in the second direction; and
a third part to connect the first part to the second part.

5. The display panel of claim 4, wherein the first part of each of the (1-1)-th output wire and the (1-2)-th output wire is under the second part, and the first part of each of the (1-4)-th output wire, the (1-5)-th output wire, and the (1-6)-th output wire is above the second part, in a plan view, and
wherein the first part of each of the (2-1)-th output wire, the (2-2)-th output wire, the (2-3)-th output wire is under the second part, and the first part of the (2-5)-th output wire and the (2-6)-th output wire is above the second part, in the plan view.

6. The display panel of claim 5, wherein the first part, the second part, and the third part of each of the (1-3)-th output wire and the (2-4)-th output wire are arranged along a same line extending in the second direction, in the plan view.

7. The display panel of claim 5, wherein the first part of the (1-3)-th output wire is under the second part, and the first part of the (2-4)-th output wire is above the second part, in the plan view.

8. The display panel of claim 5, wherein the third part includes:
an oblique part extending in a direction crossing the first direction and the second direction.

9. The display panel of claim 5, wherein the third part includes:
a plurality of connection parts, and
wherein at least a portion of the plurality of connection parts extends in mutually different directions.

10. The display panel of claim 1, further comprising:
a voltage wire interposed between the first stage and the second stage, and the plurality of pixels, and extending in the first direction.

11. The display panel of claim 10, wherein the voltage wire includes:
a first wire part, a second wire part, and a third wire part adjacent to each other in the first direction, and
wherein at least a portion of the second wire part of the voltage wire is overlapped with the plurality of first output wires and the plurality of second output wires, when viewed in a plan view.

12. The display panel of claim 11, wherein a minimum width of each of the first wire part and the third wire part in the second direction is greater than a minimum width of the second wire part in the second direction.

13. The display panel of claim 10, wherein the voltage wire includes:
a first wire pattern, a second wire pattern at a layer different from a layer for the first wire pattern, and a third wire pattern at a layer different from the layer for the first wire pattern and the layer for the second wire pattern,
wherein the first wire pattern, the second wire pattern, and the third wire pattern are electrically connected to each other, and
wherein the plurality of first output wires are at a same layer as the third wire pattern, and the plurality of first output wires are spaced apart from the third wire pattern, in a plan view.

14. The display panel of claim 13, wherein each of the plurality of second output wires includes:
a first bridge part at a same layer as the third wire pattern, and a second bridge part at a layer different from that of the third wire pattern, and
wherein the first bridge part is overlapped with the voltage wire and spaced apart from the third wire pattern, in the plan view.

15. An electronic device comprising:
a first stage including a first upper end region and a first lower end region adjacent to the first upper end region in a first direction;
a second stage spaced apart from the first stage in the first direction, and including a second upper end region and a second lower end region adjacent to the second upper end region in the first direction;
a voltage wire spaced apart from the first stage and the second stage in a second direction crossing the first direction, while extending in the first direction;
a plurality of first output wires extending in the second direction from the first stage, and crossing at least a portion of the voltage wire, in a plan view; and
a plurality of second output wires extending in the second direction from the second stage, and crossing at least a portion of the voltage wire, in the plan view,
wherein the plurality of first output wires extend from the first lower end region of the first stage, and
wherein the plurality of second output wires extend from the second upper end region of the second stage.

16. The electronic device of claim 15, wherein the plurality of first output wires include:
a (1-1)-th output wire, a (1-2)-th output wire, a (1-3)-th output wire, a (1-4)-th output wire, a (1-5)-th output wire, and a (1-6)-th output wire, and
wherein the plurality of second output wires include:
a (2-1)-th output wire, a (2-2)-th output wire, a (2-3)-th output wire, a (2-4)-th output wire, a (2-5)-th output wire, and a (2-6)-th output wire.

17. The electronic device of claim 16, comprising:
a plurality of pixels arranged in the first direction, and spaced apart from the first stage and the second stage in the second direction,
wherein each of the plurality of first output wires and the plurality of second output wires includes:
a first part adjacent to the first stage and the second stage and extending in the second direction;
a second part adjacent to the plurality of pixels and extending in the second direction; and
a third part to connect the first part to the second part,
wherein the first part of each of the (1-1)-th output wire and the (1-2)-th output wire is positioned under the second part, and the first part of each of the (1-4)-th output wire, the (1-5)-th output wire, and the (1-6)-th output wire is above the second part, when viewed in the plan view, and
wherein the first part of the (2-1)-th output wire, the (2-2)-th output wire, the (2-3)-th output wire is under the second part, and the first part of the (2-5)-th output wire and the (2-6)-th output wire is above the second part, in the plan view.

18. The electronic device of claim 17, wherein the first part, the second part, and the third part of each of the (1-3)-th output wire and the (2-4)-th output wire are arranged along a same line extending in the second direction, in the plan view.

19. The electronic device of claim 17, wherein the first part of the (1-3)-th output wire is under the second part, and the first part of the (2-4)-th output wire is above the second part, in the plan view.

20. The electronic device of claim 15, wherein the voltage wire includes:
a first wire part, a second wire part, and a third wire part adjacent to each other in the first direction, and
wherein a minimum width of each of the first wire part and the third wire part in the second direction is greater than a minimum width of the second wire part in the second direction.
